(19) United States
(12) Patent Application Publication
(10) Pub. No.: US 2024/0422976 A1
(43) Pub. Date: Dec. 19, 2024

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Dongyoung KIM, Suwon-si (KR); Jinhyun KIM, Suwon-si (KR)

(73) Assignee: Samsung Electronics Co., Ltd., Suwon-si (KR)

(21) Appl. No.: 18/656,694

(22) Filed: May 7, 2024

(30) Foreign Application Priority Data
Jun. 13, 2023 (KR) 10-2023-0075452

(51) Int. Cl. H10B 43/27; G11C 16/04; H01L 25/065; H10B 41/10; H10B 41/27; H10B 41/35; H10B 43/10; H10B 43/35; H10B 80/00

(52) U.S. Cl. CPC H10B 43/27; G11C 16/0483; H01L 25/0652; H10B 41/10; H10B 41/27; H10B 41/35; H10B 43/10; H10B 43/35; H10B 80/00; H01L 2225/06506

(57) ABSTRACT

A semiconductor device including gate electrodes stacked and spaced apart from each other in a first direction, extending by different lengths in a second direction on the second region, and each including a pad region having an upper surface exposed upwardly in the second region and a stack region other than the pad region, the gate electrodes including a first gate electrode and a second gate electrode below the first gate electrode, a first contact plug insulating layer on interlayer insulating layers in the pad region of the first gate electrode, surrounding a gate contact plug, and vertically overlapping the first gate electrode, second contact plug insulating layers alternating with the interlayer insulating layers below the pad region of the first gate electrode and surrounding the gate contact plug may be provided.

### CROSS-REFERENCE TO RELATED APPLICATION(S)

This application claims benefit of priority to Korean Patent Application No. 10-2023-0075452 filed on Jun. 13, 2023 in the Korean Intellectual Property Office, the disclosure of which is incorporated herein by reference in its entirety.

### BACKGROUND

Example embodiments of the present disclosure relate to semiconductor devices and/or data storage systems including the same.

A semiconductor device capable of storing high-capacity data in a data storage system has been required. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

Some example embodiments of the present disclosure are to provide semiconductor devices that may be easily manufactured and may have improved electrical properties and reliability.

Some example embodiments of the present disclosure is to provide data storage systems including such a semiconductor device that may be easily manufactured and may have improved electrical properties and reliability.

According to an example embodiment of the present disclosure, a semiconductor device includes a first semiconductor structure including a substrate and circuit devices on the substrate and a second semiconductor structure on the first semiconductor structure, wherein the second semiconductor structure includes a plate layer having a first region and a second region, gate electrodes stacked and spaced apart from each other in a first direction on the first region, the gate electrodes extending by different lengths in a second direction on the second region, the gate electrodes each including a pad region having an upper surface exposed upwardly in the second region and a stack region other than the pad region, the gate electrodes including a first gate electrode and a second gate electrode below the first gate electrode, interlayer insulating layers alternately stacked with the gate electrodes, channel structures penetrating through the gate electrodes, the channel structures extending in the first direction, the channel structures each including a channel layer, a gate contact plug penetrating through the pad region of the first gate electrode and the stack region of the second gate electrode, the gate contact plug electrically connected to the first gate electrode, the gate contact plug spaced apart from the second gate electrode, a first contact plug insulating layer on the interlayer insulating layers in the pad region of the first gate electrode, the first contact plug insulating layer surrounding the gate contact plug, the first contact plug insulating layer vertically overlapping the first gate electrode, and second contact plug insulating layers alternating with the interlayer insulating layers below the pad region of the first gate electrode, the second contact plug insulating layers surrounding the gate contact plug.

According to an example embodiment of the present disclosure, a semiconductor device includes a plate layer having a first region and a second region, gate electrodes stacked and spaced apart from each other in a first direction on the first region, the gate electrodes extending by different lengths in a second direction on the second region, the gate electrodes each including a pad region having an upper surface exposed upwardly in the second region and a stack region other than the pad region, the gate electrodes including a first gate electrode and a second gate electrode below the first gate electrode, interlayer insulating layers alternately stacked with the gate electrodes, a gate contact plug penetrating through the pad region of the first gate electrode and the stack region of the second gate electrode, the gate contact plug connected to the first gate electrode, the gate contact plug spaced apart from the second gate electrode, a contact plug insulating layer on the interlayer insulating layers in the pad region of the first gate electrode, the contact plug insulating layer surrounding the gate contact plug, and a sacrificial insulating pattern covering a portion of the pad region of the first gate electrode, at least a portion of a side surface of the first gate electrode, and at least a portion of a side surface of the interlayer insulating layers, the sacrificial insulating pattern including boron (B).

According to an example embodiment of the present disclosure, a data storage system, includes a semiconductor storage device including a first semiconductor structure including a substrate and circuit devices on the substrate and a second semiconductor structure on the first semiconductor structure, and a controller electrically connected to the semiconductor storage device through an input/output pad and configured to control the semiconductor storage device, wherein the second semiconductor structure includes a plate layer having a first region and a second region, gate electrodes stacked and spaced apart from each other in a first direction on the first region, the gate electrodes extending by different lengths in a second direction on the second region, the gate electrodes each including a pad region having an upper surface exposed upwardly in the second region and a stack region other than the pad region, the gate electrodes including a first gate electrode and a second gate electrode below the first gate electrode, interlayer insulating layers alternately stacked with the gate electrodes, channel structures penetrating through the gate electrodes, extending in the first direction, the channel structures each including a channel layer, a gate contact plug penetrating through the pad region of the first gate electrode and the stack region of the second gate electrode, the gate contact plug electrically connected to the first gate electrode, and the gate contact plug spaced apart from the second gate electrode, a first contact plug insulating layer on the interlayer insulating layers in the pad region of the first gate electrode, the first contact plug insulating layer surrounding the gate contact plug, and the first contact plug insulating layer vertically overlapping the first gate electrode, second contact plug insulating layers alternating with the interlayer insulating layers below the pad region of the first gate electrode, and the second contact plug insulating layers surrounding the gate contact plug, and a sacrificial insulating pattern covering a portion of the pad region of the first gate electrode, at least a portion of a side surface of the first gate electrode, and at least a portion of a side surface of the interlayer insulating layers.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan view illustrating a semiconductor device according to an example embodiment of the present disclosure;

FIGS. 2A and 2B are cross-sectional views illustrating a semiconductor device according to an example embodiment of the present disclosure;

FIG. 2C is an enlarged view illustrating a portion of a semiconductor device according to an example embodiment of the present disclosure;

FIG. 3 is an enlarged view illustrating a portion of a semiconductor device according to an example embodiment of the present disclosure;

FIG. 4 is an enlarged view illustrating a portion of a semiconductor device according to an example embodiment of the present disclosure;

FIG. 5 is an enlarged view illustrating a portion of a semiconductor device according to an example embodiment of the present disclosure;

FIG. 6 is an enlarged view illustrating a portion of a semiconductor device according to an example embodiment of the present disclosure;

FIG. 7 is an enlarged view illustrating a portion of a semiconductor device according to an example embodiment of the present disclosure;

FIG. 8 is an enlarged view illustrating a portion of a semiconductor device according to an example embodiment of the present disclosure;

FIG. 9 is an enlarged view illustrating a portion of a semiconductor device according to an example embodiment of the present disclosure;

FIG. 10 is a cross-sectional view illustrating a semiconductor device according to example embodiments of the present disclosure;

FIGS. 11 to 20 are cross-sectional views and enlarged views illustrating a method of manufacturing a semiconductor device according to an example embodiment of the present disclosure;

FIG. 21 is a view illustrating a data storage system including a semiconductor device according to an example embodiment of the present disclosure;

FIG. 22 is a perspective view illustrating a data storage system including a semiconductor device according to an example embodiment of the present disclosure; and

FIG. 23 is a cross-sectional view illustrating a semiconductor package according to an example embodiment of the present disclosure.

### DETAILED DESCRIPTION

Hereinafter, some example embodiments of the present disclosure will be described as follows with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

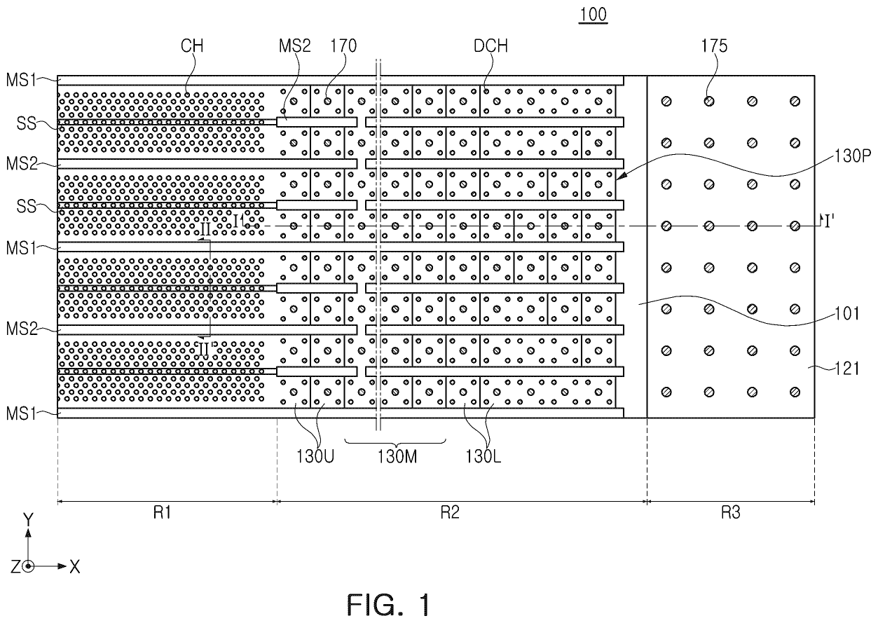

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B. FIG. 1 is a plan view illustrating a semiconductor device according to an example embodiment.

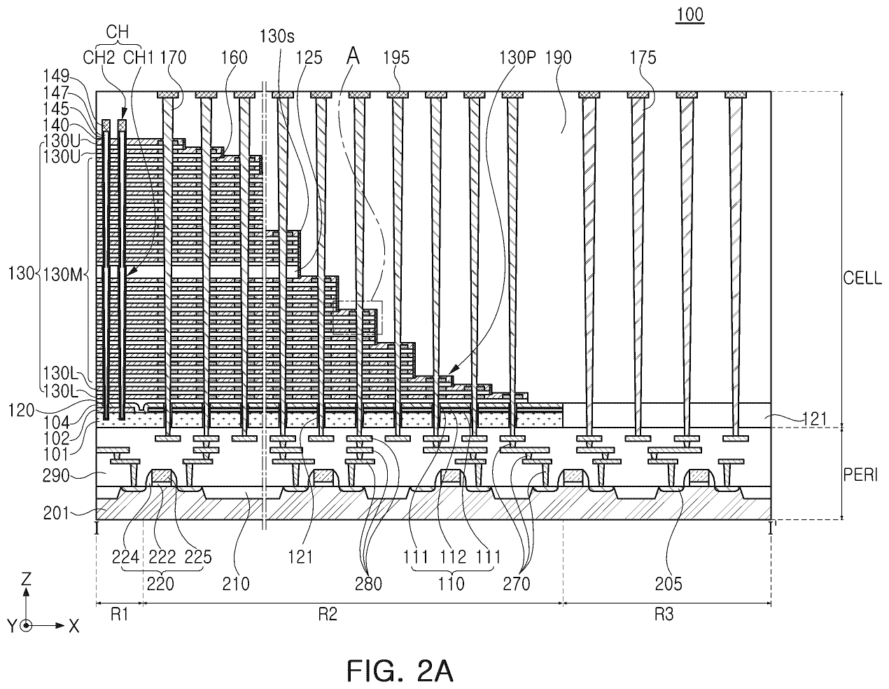

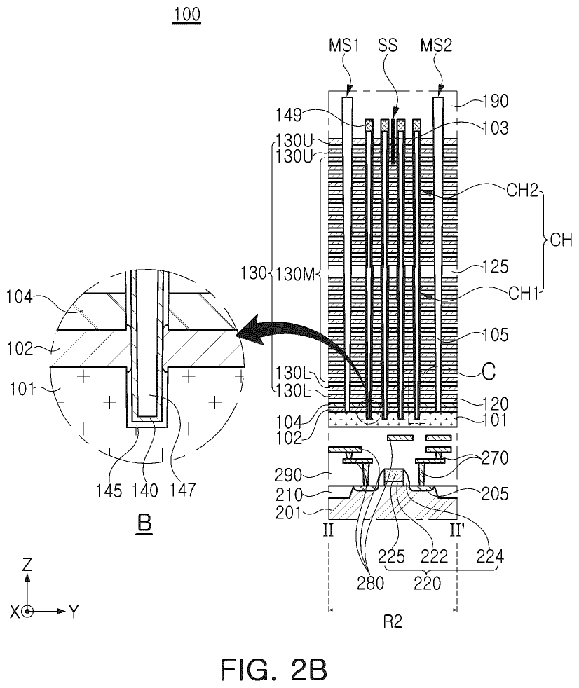

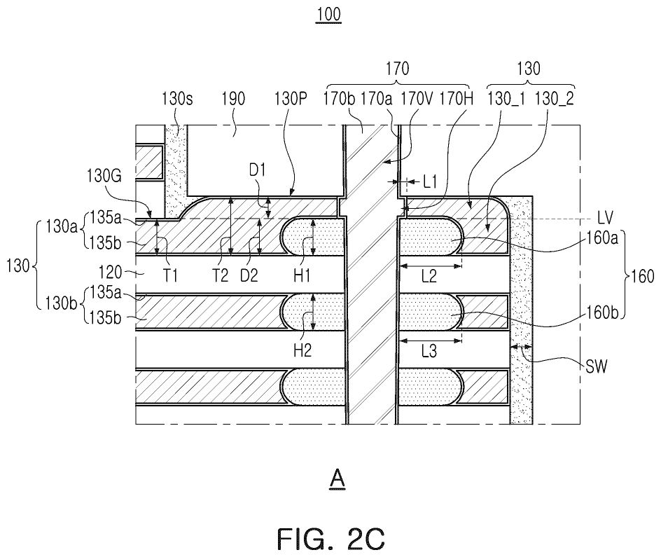

FIGS. 2A and 2B are cross-sectional views illustrating a semiconductor device according to an example embodiment. FIG. 2A illustrates a cross-section taken along line I-I′ in FIG. 1, and FIG. 2B illustrates a cross-section taken along line II-II′ in FIG. 1.

FIG. 2C is an enlarged view illustrating a portion of a semiconductor device according to an example embodiment, illustrating region “A” in FIG. 2A.

Referring to FIGS. 1 to 2C, a semiconductor device 100 may include a peripheral circuit region PERI, which is a first semiconductor structure including a substrate 201, and a memory cell region CELL, which is a second semiconductor structure including a plate layer 101. The memory cell region CELL may be disposed on the peripheral circuit region PERI. In some example embodiments, conversely, the memory cell region CELL may be disposed below the peripheral circuit region PERI.

The peripheral circuit region PERI may include a substrate 201, source/drain regions 205 and device isolation layers 210 in the substrate 201, circuit devices 220 disposed on the substrate 201, circuit contact plugs 270, circuit interconnection lines 280, and peripheral region insulating layer 290.

The substrate 201 may have an upper surface extending in the X-direction and the Y-direction. In the substrate 201, an active region may be defined by the device isolation layers 210. The source/drain regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 220 may include planar transistors. Each of the circuit devices 220 may include a circuit gate dielectric layer 222, a spacer layer 224 and a circuit gate electrode 225. The source/drain regions 205 may be disposed in the substrate 201 on both sides of the circuit gate electrode 225.

The peripheral region insulating layer 290 may be disposed on the circuit devices 220 on the substrate 201. The circuit contact plugs 270 may penetrate through the peripheral region insulating layer 290 and may be connected to the source/drain regions 205. Electrical signals may be applied to the circuit devices 220 by the circuit contact plugs 270. In a region not illustrated, the circuit contact plugs 270 may also be connected to the circuit gate electrode 225. The circuit interconnection lines 280 may be connected to the circuit contact plugs 270 and may be disposed in a plurality of layers.

The memory cell region CELL may include a plate layer 101 having a first region R1 and a second region R2, gate electrodes 130 stacked on the plate layer 101, interlayer insulating layers 120 alternately stacked with the gate electrodes 130, channel structures CH disposed to penetrate through the stack structure of gate electrodes 130, first and second isolation regions MS1 and MS2 extending through the stack structure of the gate electrodes 130, gate contact plugs 170 extending through the gate electrodes 130 in the second region R2, contact plug insulating layers 160 surrounding the gate contact plugs 170, a sacrificial insulating pattern 130s covering a side surface of the stack structure of gate electrodes 130, and through-plugs 175 disposed in the third region R3 on an external side of the plate layer 101.

The memory cell region CELL may further include a first horizontal conductive layer 102 on the first region R1, a horizontal insulating layer 110 disposed in parallel with the first horizontal conductive layer 102 on the second region R2 of the plate layer 101, a first horizontal conductive layer 102 and a second horizontal conductive layer 104 on the horizontal insulating layer 110, the substrate insulating layer 121 penetrating through the plate layer 101, upper isolation regions SS penetrating through a portion of the stack structure of gate electrodes 130, dummy channel structures DCH disposed to penetrate through the stack structure of gate electrodes 130 in the second region R2, a cell region insulating layer 190, and cell interconnection lines 195.

In the first region R1 of the plate layer 101, the gate electrodes 130 may be vertically stacked and the channel structures CH may be disposed, and memory cells may be disposed in the first region R1. In the second region R2, the gate electrodes 130 may extend by different lengths, and the second region R2 may be provided to electrically connect the memory cells to the peripheral circuit region PERI. The second region R2 may be disposed on at least one end of first region R1 in at least one direction, for example, the X-direction.

The plate layer 101 may have an upper surface extending in the X-direction and the Y-direction. The plate layer 101 may include a semiconductor material, for example, a group IV semiconductor, a group III-V compound semiconductor, or a group II-VI compound semiconductor. For example, a group IV semiconductor may include silicon, germanium, or silicon-germanium. The plate layer 101 may further include impurities. The plate layer 101 may be provided as a polycrystalline semiconductor layer such as a polycrystalline silicon layer or an epitaxial layer.

The gate electrodes 130 may be vertically stacked and spaced apart from each other on the plate layer 101 and may form a stack structure. The gate electrodes 130 may include lower gate electrodes 130L forming a gate of a ground selection transistor, memory gate electrodes 130M forming a plurality of memory cells, and upper gate electrodes 130U forming a gate of a string selection transistor. The number of the memory gate electrodes 130M included in memory cells may be determined depending on capacity of the semiconductor device 100. In some example embodiments, each of the number of the upper gate electrodes 130U and the number of the lower gate electrodes 130L may be 1 to 4 or more, and may have a structure the same as or different from that of the memory gate electrodes 130M. In some example embodiments, the gate electrodes 130 may further include some gate electrode 130 that is disposed below the upper and/or lower gate electrodes 130L of the upper gate electrodes 130U, and forms an erase transistor used for an erase operation using gate induced drain leakage (GIDL) phenomenon. Further, some of the memory gate electrodes 130M adjacent to a portion of the gate electrodes 130, for example, upper or lower gate electrodes 130U and 130L, may be dummy gate electrodes.

The gate electrodes 130 may be vertically spaced apart from each other and stacked on the first region R1, and may extend by different lengths from the first region R1 to the second region R2 and may form a step structure in a staircase shape. As illustrated in FIG. 2A, the gate electrodes 130 may form a step structure between the gate electrodes 130 in the X-direction, and may also be disposed to have a step structure in the Y-direction.

Due to the step structure, each of the gate electrodes 130 may have regions in which the lower gate electrode 130 may extend longer than the upper gate electrode 130 and may be exposed upwardly from the interlayer insulating layers 120, and the regions may be referred to as pad regions 130P. In each gate electrode 130, the pad region 130P may include an end in the X-direction. The pad region 130P may correspond to a portion of the gate electrode 130 disposed in an upper portion in each region among the gate electrodes 130 forming the stack structure in the second region R2 of the plate layer 101. The gate electrodes 130 may be connected to the gate contact plugs 170 in the pad regions 130P. In each of the gate electrodes 130, the remaining regions other than the pad region 130P may be referred to as a stack region 130G. The stack region 130G may be a portion not exposed upwardly from the interlayer insulating layers 120.

The gate electrodes 130 may have an increased thickness in the pad regions 130P. The thickness of the first gate electrodes 130a may be increased in a manner in which a level of an upper surface may be increased while a level of a lower surface may be constant. As illustrated in FIG. 2C, the first gate electrodes 130a may extend from the first region R1 toward the second region R2 with a first gate thickness T1, and may have a second gate thickness T2 greater than the first gate thickness T1 in the pad regions 130P. The second gate thickness T2 may range from about 150% to about 210% of the first gate thickness T1, but example embodiments thereof are not limited thereto.

The gate electrodes 130 may be disposed to be isolated from each other in the Y-direction by the first isolation regions MS1 extending in the X-direction. The gate electrodes 130 between a pair of first isolation regions MS1 may form a memory block, but the range of the memory block is not limited thereto. The gate electrodes 130 may include a metal material, such as tungsten (W). In some example embodiments, the gate electrodes 130 may include polycrystalline silicon or a metal silicide material.

Referring to FIG. 2C, the gate electrodes 130 may have an increased thickness in the pad regions 130P. The thickness of the gate electrodes 130 may increase in a manner in which a level of an upper surface is increased while a level of a lower surface is constant. As illustrated in FIG. 2C, the gate electrodes 130 may extend from the first region R1 toward the second region R2 with a first gate thickness T1, and as illustrated in the enlarged portion in FIG. 2C, the gate electrodes 130 may have a second gate thickness T2 greater than the first gate thickness T1 in the pad regions 130P.

The gate electrodes 130 may include a first gate electrode 130a included in the pad region 130P and the second gate electrode 130b therebelow. The first and second gate electrodes 130a and 130b may include a first layer 135a and a second layer 135b, respectively. The first layer 135a may cover an upper surface and a lower surface of the second layer 135b and may extend to a region between the channel structure CH and the second layer 135b. The first layer 135a may include a high-x dielectric material such as aluminum oxide (AlO), and the second layer 135b may include a conductive material. For example, the second layer 135b may include at least one of titanium (Ti), titanium nitride (TiN), tantalum (Ta), tantalum nitride (TaN), tungsten (W), or tungsten nitride (WN). In some example embodiments, the first and second gate electrodes 130a and 130b may include polycrystalline silicon or a metal-semiconductor compound.

The first gate electrode 130a may include a first portion 130_1 covering a side surface and an upper surface of the first contact plug insulating layer 160a and disposed on a level higher than a level LV of an upper surface of the first contact plug insulating layer 160a, and a second portion 130_2 disposed between the level LV of the upper surface of the first contact plug insulating layer 160a and a level of a lower surface of the first contact plug insulating layer 160a. In an example embodiment, a thickness of the first portion 130_1 may be substantially equal to or smaller than a thickness of the second portion 130_2, but example embodiments thereof are not limited thereto.

The interlayer insulating layers 120 may be disposed between the gate electrodes 130. Similar to the gate electrodes 130, the interlayer insulating layers 120 may be spaced apart from each other in a direction perpendicular to the upper surface of the plate layer 101 and may extend in the X-direction. The interlayer insulating layers 120 may include an insulating material such as silicon oxide or silicon nitride.

As illustrated in FIG. 1, the channel structures CH may form a memory cell string, and may be spaced apart from each other while forming rows and columns on the first region R1. The channel structures CH may be disposed to form a grid pattern or may be disposed in a zigzag pattern in one direction. The channel structures CH may have a column shape and may have an inclined side surface having a width decreasing the plate layer 101 depending on an aspect ratio.

The channel structures CH may include first and second channel structures CH1 and CH2 which may be vertically stacked, as illustrated in FIG. 2A. Each of the channel structures CH may have a form in which a first channel structure CH1 penetrating through the lower stack structure of the gate electrodes 130 and a second channel structure CH2 penetrating through the upper stack structure of the gate electrodes 130 are connected to each other, and may have a bent portion due to a difference in a connection region. However, in example embodiments, the number of channel structures stacked in the Z-direction may be varied.

As illustrated in the enlarged view in FIG. 2B, a channel layer 140 may be disposed in the channel structures CH. In the channel structures CH, the channel layer 140 may be formed in an annular shape surrounding an internal channel filling insulating layer 147. The channel layer 140 may be connected to the first horizontal conductive layer 102 in a lower portion. The channel layer 140 may include a semiconductor material such as polycrystalline silicon or monocrystalline silicon.

The gate dielectric layer 145 may be disposed between the gate electrodes 130 and the channel layer 140. Although not specifically illustrated, the gate dielectric layer 145 may include a tunneling layer, a charge storage layer, and a blocking layer stacked in order from the channel layer 140. The tunneling layer may tunnel electric charges into the charge storage layer, and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include silicon oxide (SiO₂), silicon nitride (Si₃N₄), silicon oxynitride (SiON), a high-k dielectric material, or a combination thereof. In some example embodiments, at least a portion of the gate dielectric layer 145 may extend in a horizontal direction along the gate electrodes 130. The channel pad 149 may be disposed only on an upper end of the upper second channel structure CH2. The channel pad 149 may include, for example, doped polycrystalline silicon.

The channel layer 140, the gate dielectric layer 145, and the channel filling insulating layer 147 may be connected to each other between the first channel structure CH1 and the second channel structure CH2. An upper interlayer insulating layer 125 having a relatively great thickness may be disposed between the first channel structure CH1 and the second channel structure CH2, that is, between the lower stack structure and the upper stack structure. However, the shape of the interlayer insulating layers 120 and upper interlayer insulating layer 125 may be varied in example embodiments.

The first and second isolation regions MS1 and MS2 may penetrate through the gate electrodes 130 and may extend in the X-direction. The first and second isolation regions MS1 and MS2 may be disposed parallel to each other. The first and second isolation regions MS1 and MS2 may be connected to the plate layer 101 through the entire gate electrodes 130 stacked on the plate layer 101. The first isolation regions MS1 may extend as an integrated region in the X-direction, and the second isolation regions MS2 may extend intermittently between a pair of first isolation regions MS1 or may be disposed only in a portion of the regions. However, in example embodiments, the arrangement order and the number of first and second isolation regions MS1 and MS2 are not limited to the example illustrated in FIG. 1. As illustrated in FIG. 2B, the isolation insulating layer 105 may be disposed in the first and second isolation regions MS1 and MS2.

The gate contact plugs 170 may penetrate through the uppermost gate electrodes 130 and the contact plug insulating layers 160 in the second region R2 and may be connected to the pad regions 130P of the gate electrodes 130. The gate contact plugs 170 may penetrate through at least a portion of the cell region insulating layer 190 and may be connected to each of the pad regions 130P of the gate electrodes 130 exposed upwardly. The gate contact plugs 170 may penetrate through the plate layer 101, the second horizontal conductive layer 104, and the horizontal insulating layer 110 and may be connected to the circuit interconnection lines 280 in the peripheral circuit region PERI below the gate electrodes 130. The gate contact plugs 170 may be spaced apart from the plate layer 101, the second horizontal conductive layer 104, and the horizontal insulating layer 110 by the substrate insulating layer 121. In some example embodiments, the gate contact plugs 170 may not extend into the peripheral circuit region PERI, and a lower end of the peripheral circuit region PERI may be disposed in the substrate insulating layer 121.

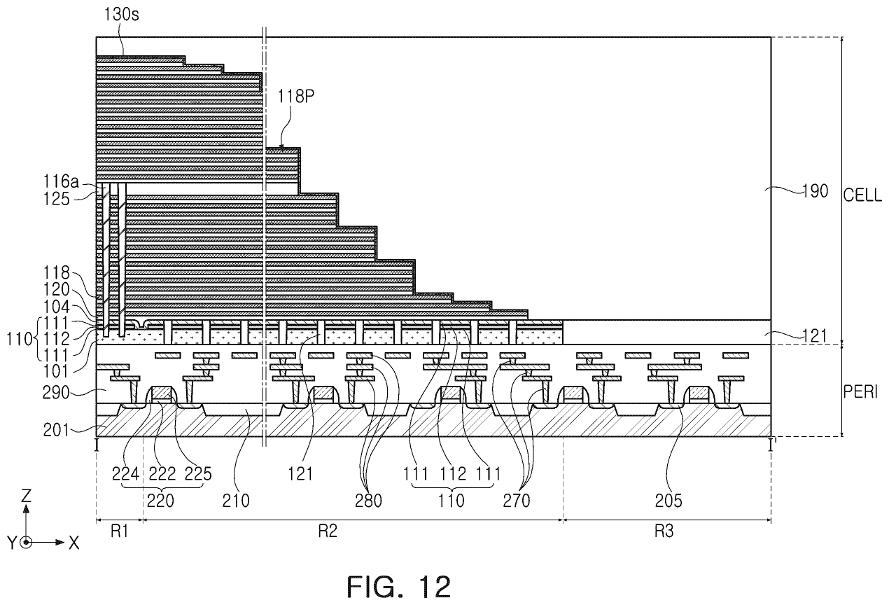

As illustrated in FIG. 2C, each of the gate contact plugs 170 may include a vertical extension portion 170V extending along the Z-direction and a horizontal extension portion 170H extending horizontally from the vertical extension portion 170V and in contact with the pad regions 130P. The vertical extension portion 170V may have a cylindrical shape having a width decreasing toward the plate layer 101 due to an aspect ratio. The horizontal extension portion 170H may be disposed along a circumference of the vertical extension portion 170V and may extend from a side surface of the vertical extension portion 170V with a first length L1. The first length L1 may be smaller than the second length L2 from a side surface of the vertical extension portion 170V to an end of the first contact plug insulating layers 160a. In other words, the first length L1 may be smaller than the second length L2 of the vertical extension portion 170V, in a horizontal direction (e.g., X-direction). Referring to FIG. 12, each of the sacrificial insulating layers 118 may have substantially the same thickness. In the subsequent process in FIG. 15, when first tunnel portions TL1 and second tunnel portions TL2 are formed, since the thickness of the sacrificial insulating layers 118 is substantially the same, the amount of etching in the horizontal direction may be substantially the same. Accordingly, referring to FIG. 2C, the second length L2 may be substantially equal to the third length L3 from a side surface of the vertical extension portion 170V to an end of the second contact plug insulating layers 160b. In other words, the first length L1 may be smaller than the second length L2 of the vertical extension portion 170V in the horizontal direction.

The gate contact plugs 170 may include, for example, at least one of tungsten (W), copper (Cu), aluminum (Al), or an alloy thereof. In some example embodiments, the gate contact plugs 170 may further include barrier layers on side walls and bottom surfaces of contact holes on which the gate contact plugs 170 are disposed. The barrier layer may include, for example, at least one of titanium (Ti), titanium nitride (TiN), tantalum (Ta), or tantalum nitride (TaN).

The contact plug insulating layers 160 may include first contact plug insulating layers 160a disposed on the interlayer insulating layers 120 in the pad region 130P, surrounding the gate contact plugs 170, and vertically overlapping the first gate electrodes 130a, and second contact plug insulating layers 160b disposed alternately with the interlayer insulating layers 120 and surrounding the gate contact plugs 170 below the pad region 130P of the first gate electrode 130a.

An internal side surface of the contact plug insulating layers 160 may surround the gate contact plugs 170, and an external side surface of the contact plug insulating layers 160 may be surrounded by the gate electrodes 130. In an example embodiment, the first gate electrodes 130a may be disposed to surround upper and side surfaces of the first contact plug insulating layers 160a in the pad region 130P. The second contact plug insulating layers 160b may surround the gate contact plugs 170 and be alternately disposed with the interlayer insulating layers 120. The second contact plug insulating layers 160b may be disposed to surround side surfaces of the gate contact plugs 170 below the pad regions 130P. Because the gate contact plugs 170 are in contact with the first gate electrode 130a on the upper surfaces of the first contact plug insulating layers 160a, the gate contact plugs 170 may be physically and electrically connected to the first gate electrode 130a, and may be electrically isolated from the second gate electrodes 130b below the first gate electrode 130a by the second contact plug insulating layers 160b. The contact plug insulating layers 160 may include an insulating material such as at least one of silicon oxide, silicon nitride, or silicon oxynitride.

Because the first gate electrodes 130a are formed after the first contact plug insulating layers 160a are formed, the first gate electrodes 130a may cover a side surface and an upper surface of the first contact plug insulating layers 160a.

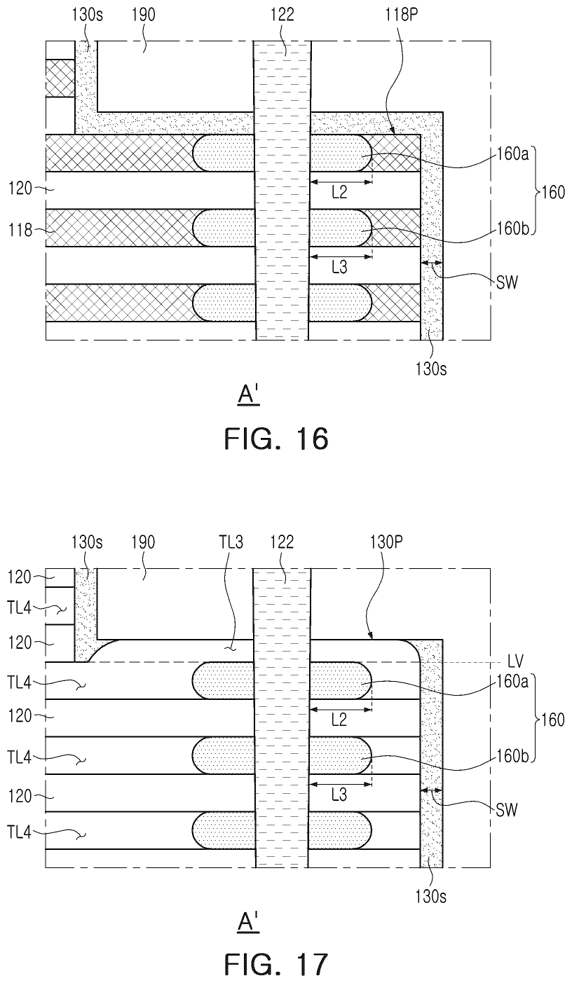

Referring to FIG. 12, each of the sacrificial insulating layers 118 replaced with gate electrodes 130 may be formed to have the same thickness. In the subsequent process in FIGS. 15 and 16, because the first contact plug insulating layers 116a and the second contact plug insulating layers 116b are formed in the first tunnel portions TL1 and the second tunnel portions TL2 from which the sacrificial insulating layers 118 are removed, the first contact plug insulating layers 160a may have a first thickness H1, and the second contact plug insulating layers 160b may have a second thickness H2 substantially equal to the first thickness H1. Also, the first gate thickness T1 of the first gate electrode 130a and the first thickness H1 of the first contact plug insulating layers 160a may be substantially the same.

The sacrificial insulating pattern 130s may cover a portion of the pad region 130P, at least a portion of the side surface of the first gate electrode 130a, and at least a portion of the side surface of the interlayer insulating layers 120, and may include boron (B). The sacrificial insulating pattern 130s may further include nitrogen (N). The sacrificial insulating pattern 130s may have an amorphous structure. In an example embodiment, the sacrificial insulating pattern 130s may include an insulating material. The sacrificial insulating pattern 130s may include, for example, at least one of boron nitride (BN) or boron carbonitride (BN). In an example embodiment, the sacrificial insulating pattern 130s may further include carbon (C). Carbon (C) may be in a range of about 15 at % or lower. For example, carbon (C) may be in a range of about 15 at % or lower. After the sacrificial insulating pattern 130s is formed in the process in FIG. 12, the sacrificial insulating pattern 130s may include a material stable for subsequent processes. The sacrificial insulating pattern 130s may include a material having etch selectivity with respect to the sacrificial insulating layers (118, see FIG. 12) and the interlayer insulating layers 120 under a specific etching condition.

In an example embodiment, because the first portion 130_1 is formed by removing a portion of the sacrificial insulating pattern 130s, the thickness SW of the sacrificial insulating pattern 130s may be substantially the same as the thickness D1 of the first portion 130_1. The thickness SW of the sacrificial insulating pattern 130s may be smaller than the thickness D2 of the second portion 130_2 and the thickness H1 of the first contact plug insulating layers 160a, but example embodiments thereof are not limited thereto.

The gate contact plugs 170 may penetrate through the stack region 130G of the second gate electrode 130b disposed below the first gate electrode 130a while penetrating through the pad region 130P of the first gate electrode 130a among the gate electrodes 130.

The gate contact plugs 170 may be electrically connected to the first gate electrode 130a and may be electrically isolated from the other gate electrodes 130 including the second gate electrode 130b. The contact plug insulating layer 160 may be disposed between the second gate electrode 130b and the gate contact plugs 170 and electrically isolate the second gate electrode 130b from the gate contact plug.

The gate contact plugs 170 may include at least one of metal or metal nitride. The gate contact plugs 170 may include a first conductive liner 170a and a first conductive plug 170b. The first conductive liner 170a may cover a side surface and a lower surface of the first conductive plug 170b. The first conductive liner 170a may include a bent portion bent in a horizontal direction from a portion extending in the Z-direction. The first conductive liner 170a may be a barrier layer for preventing or blocking diffusion, and may include, for example, at least one of titanium (Ti), titanium nitride (TiN), tantalum (Ta), or tantalum nitride (TaN). The first conductive plug 170b may include a metal material, for example, at least one of tungsten (W), titanium TI, copper (Cu), aluminum (Al), or an alloy thereof. In some example embodiments, the first conductive liner 170a may not be provided, and the gate contact plugs 170 may include the first conductive plug 170b.

The through-plugs 175 may be disposed in the third region R3 of the memory cell region CELL, which is an external side region of the plate layer 101, and may penetrate through the cell region insulating layer 190 and may extend to the peripheral circuit region PERI. The through-plugs 175 may be disposed to connect the cell interconnection lines 195 of the memory cell region CELL to the circuit interconnection lines 280 of the peripheral circuit region PERI. The through-plugs 175 may include a conductive material, for example, a metal material such as tungsten (W), copper (Cu), or aluminum (Al). The through-plugs 175 may be formed in the same process as the process of forming the gate contact plugs 170, may include the same material as that of the gate contact plugs 170, and may have the same internal structure as that of the gate contact plugs 170.

The first and second horizontal conductive layers 102 and 104 may be stacked in order on the upper surface of the first region R1 of the plate layer 101. The first horizontal conductive layer 102 may not extend into the second region R2 of the plate layer 101, and the second horizontal conductive layer 104 may extend into the second region R2.

The first horizontal conductive layer 102 may function as a portion of a common source line of the semiconductor device 100, and may function as a common source line together with the plate layer 101, for example. As illustrated in the enlarged view in FIG. 2B, the first horizontal conductive layer 102 may be directly connected to the channel layer 140 around the channel layer 140.

The second horizontal conductive layer 104 may be in contact with the plate layer 101 in regions at which the first horizontal conductive layer 102 and the horizontal insulating layer 110 are not disposed. The second horizontal conductive layer 104 may be bent by covering an end of the first horizontal conductive layer 102 or the horizontal insulating layer 110 in the regions and may extend to the plate layer 101.

The first and second horizontal conductive layers 102 and 104 may include a semiconductor material, and for example, both the first and second horizontal conductive layers 102 and 104 may include polycrystalline silicon. In this case, at least the first horizontal conductive layer 102 may be a doped layer, and the second horizontal conductive layer 104 may be a doped layer or a layer including impurities diffused from the first horizontal conductive layer 102. However, in some example embodiments, the second horizontal conductive layer 104 may be replaced with an insulating layer.

The horizontal insulating layer 110 may be disposed on the plate layer 101 parallel to the first horizontal conductive layer 102 in at least a portion of the second region R2. The horizontal insulating layer 110 may include first and second horizontal insulating layers 111 and 112 alternately stacked on the second region R2 of the plate layer 101. In the example embodiment, the first horizontal insulating layers 111 may be a plurality of layers covering upper and lower surfaces of the second horizontal insulating layer 112. The horizontal insulating layer 110 may be layers remaining after a portion is replaced with the first horizontal conductive layer 102 in a process of manufacturing the semiconductor device 100

The horizontal insulating layer 110 may include silicon oxide, silicon nitride, silicon carbide, or silicon oxynitride. The first horizontal insulating layers 111 and the second horizontal insulating layer 112 may include different insulating materials. For example, the first horizontal insulating layers 111 may be formed of the same material as that of the interlayer insulating layers 120, and the second horizontal insulating layer 112 may be formed of a material different from that of the interlayer insulating layers 120.

The substrate insulating layer 121 may also be disposed on the external side of the third region R3, that is, the plate layer 101. The substrate insulating layer 121 may include, for example, silicon oxide, silicon nitride, silicon carbide, or silicon oxynitride. In some example embodiments, the substrate insulating layer 121 may also extend in the first direction in the second region R2 and may be disposed to penetrate through the plate layer 101, the horizontal insulating layer 110, and the second horizontal conductive layer 104. The substrate insulating layer 121 may be disposed to surround each of the gate contact plugs 170. Accordingly, the gate contact plugs 170 connected to different gate electrodes 130 may be electrically isolated from each other.

As illustrated in FIG. 1, upper isolation regions SS may extend in the X-direction between first isolation regions MS1 and second isolation regions MS2 in the first region R1. The upper isolation regions SS may isolate three gate electrodes 130 including, for example, the upper gate electrodes 130U, from each other in the Y-direction, as illustrated in FIG. 2B. However, the number of gate electrodes 130 isolated by upper isolation regions SS may be varied in example embodiments. The upper gate electrodes 130U isolated by the upper isolation regions SS may form different string selection lines. An upper insulating layer 103 may be disposed in the upper isolation regions SS. The upper isolation insulating layer 103 may include an insulating material, for example, silicon oxide, silicon nitride, or silicon oxynitride.

The dummy channel structures DCH may be spaced apart from each other while forming rows and columns in the second region R2. The dummy channel structures DCH may have a larger size than that of the channel structures CH on the plan view, but example embodiments thereof are not limited thereto. The dummy channel structures DCH may be further disposed in a portion of the first region R1 adjacent to the second region R2. The dummy channel structures DCH may not be electrically connected to upper interconnection structures, and differently from the channel structures CH, the dummy channel structures DCH may not form a memory cell string in the semiconductor device 100.

The dummy channel structures DCH may have a structure the same as or different from that of the channel structures CH. When the dummy channel structures DCH are formed together with channel structures CH, the dummy channel structures DCH may have the same structure as the channel structures CH. When the dummy channel structures DCH are formed using a portion of the gate contact plugs 170 during the process of forming the gate contact plugs 170, the dummy channel structures DCH may have a different structure from the channel structures CH. In this case, for example, the dummy channel structures DCH may have a structure filled with an insulating material such as oxide.

The cell region insulating layer 190 may be disposed to cover the plate layer 101, the gate electrodes 130 and the peripheral region insulating layer 290 on the plate layer 101. The cell region insulating layer 190 may be formed of an insulating material or may include a plurality of insulating layers.

The cell interconnection lines 195 may form an upper interconnection structure electrically connected to the memory cells in the memory cell region CELL. The cell interconnection lines 195 may be connected to the gate contact plugs 170 and the through-plugs 175, and may be electrically connected to the gate electrodes 130 and the channel structures CH. In example embodiments, the number of the contact plugs and the interconnection lines included in the upper interconnection structure may be varied. The cell interconnection lines 195 may include metal, for example, tungsten (W), copper (Cu), or aluminum (Al).

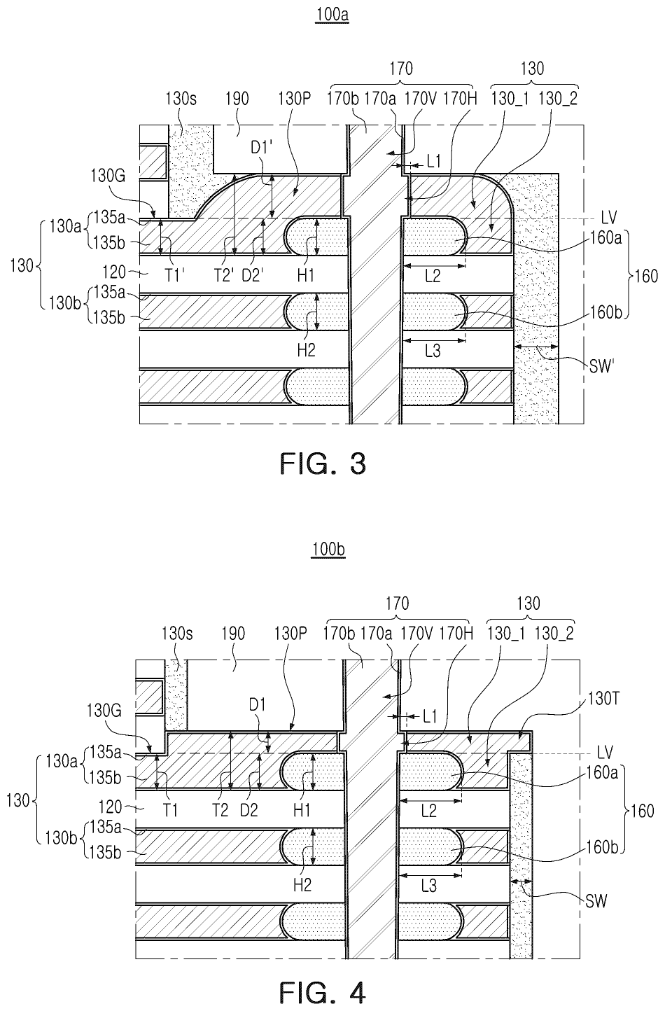

In FIGS. 3 to 10, the same reference numerals as in FIGS. 2A to 2C may indicate corresponding configurations, and the descriptions overlapping the above descriptions will not be provided.

FIG. 3 is an enlarged view illustrating a portion of a semiconductor device according to an example embodiment, illustrating a region corresponding to FIG. 2C.

Referring to FIG. 3, because the first portion 130_1 is formed by removing a portion of the sacrificial insulating pattern 130s, in the process in FIG. 12, when the thickness SW′ of the sacrificial insulating pattern 130s is formed to be greater than the thickness SW of the sacrificial insulating pattern 130s of FIG. 2C, the thickness D1′ of the first portion 130_1 of the semiconductor device 100a may be greater than the thickness D2′ of the second portion 130_2. In this case, a contact area between the first gate electrode 130a and the gate contact plug 170 may be increased. In another example embodiment, the first gate thickness T1′ and the second gate thickness T2′ of the first gate electrode 130a may be adjusted in the range in which electrical properties may improve.

FIG. 4 is an enlarged view illustrating a portion of a semiconductor device according to an example embodiment, illustrating a region corresponding to FIG. 2C.

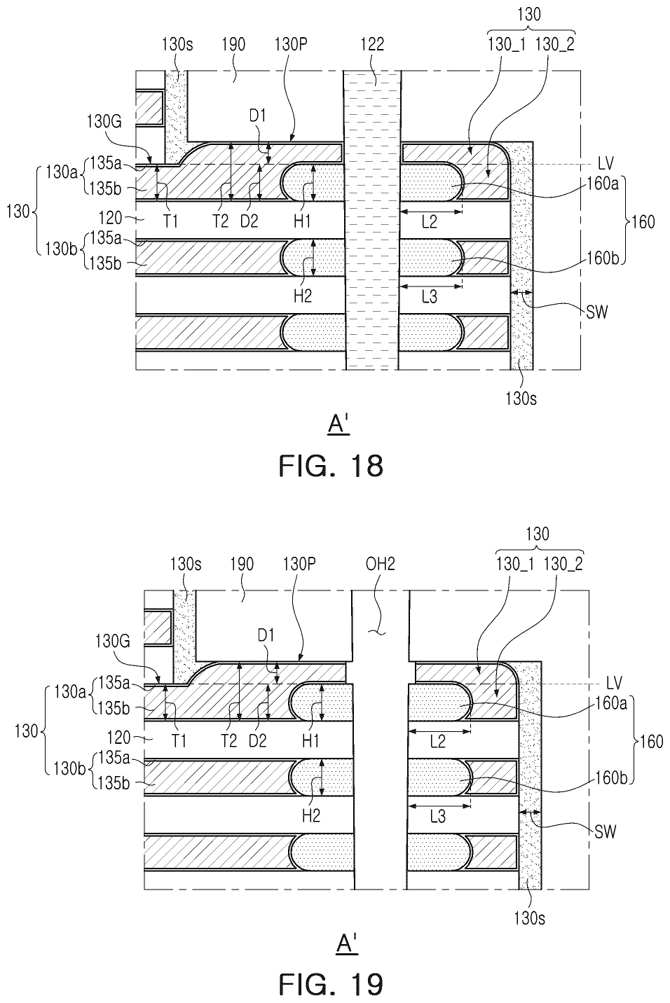

Referring to FIG. 4, the first gate electrode 130a of the semiconductor device 100b may include a protrusion portion 130T protruding from a side surface of the second portion 130_2 toward an upper portion of the sacrificial insulating pattern 130s. In an example embodiment, the protrusion portion 130T may cover an upper surface of the sacrificial insulating pattern 130s. The protrusion portion 130T may be formed when the sacrificial insulating pattern 130s is over-etched in the process in FIG. 17. Accordingly, the first portion 130_1 may be in contact with a portion of the side surface of the interlayer insulating layers 120 and a lower portion of the sacrificial insulating pattern 130s. The sacrificial insulating pattern 130s may insulate the first gate electrode 130a from other gate electrodes 130. In another example embodiment, the lower surface of the protrusion portion 130T may have a rounded shape or a curved surface. The above description of the protrusion portion 130T may also be applied to another example embodiment.

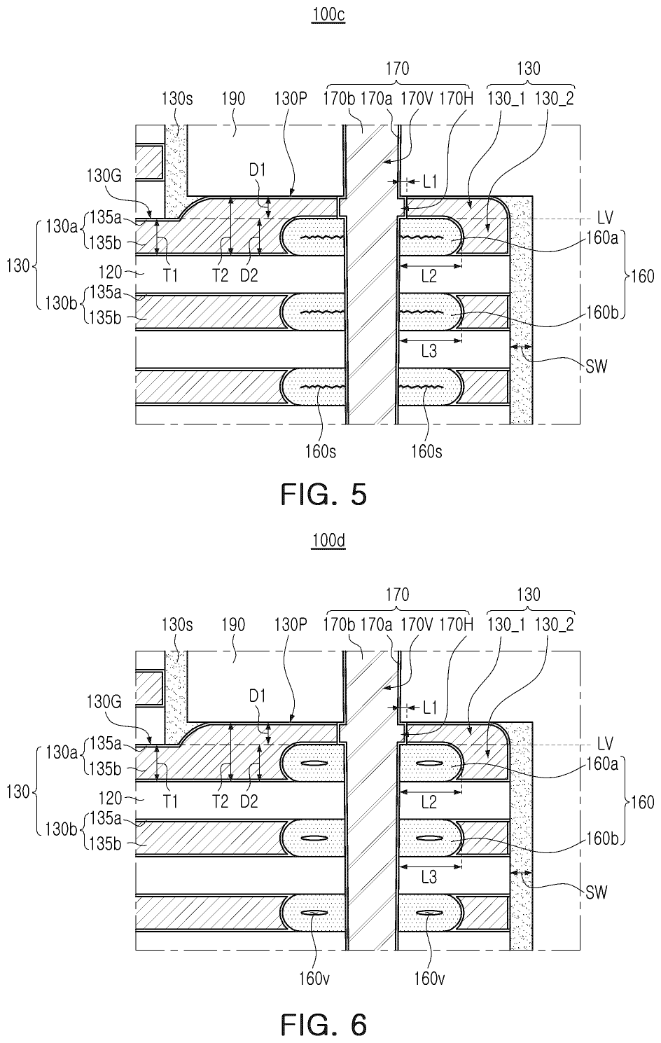

FIG. 5 is an enlarged view illustrating a portion of a semiconductor device according to an example embodiment, illustrating a region corresponding to FIG. 2C.

Referring to FIG. 5, a semiconductor device 100c may further include a seam 160s in contact plug insulating layers 160. The seam 160s may be an interfacial surface between upper grains of the contact plug insulating layers 160 and lower grains of the contact plug insulating layers 160. In an example embodiment, at least one of the first contact plug insulating layers 160a and the second contact plug insulating layers 160b may include a seam 160s formed in a second direction (e.g., X-direction). The seam 160s may be in contact with the gate contact plugs 170 on one side. Referring to the process in FIG. 16, the seam 160s may be formed in a process in which the contact plug insulating layers 160 fill the first tunnel portions (TL1, see FIG. 15) and the second tunnel portions (TL2, see FIG. 15). In some example embodiments, even when the seam 160s are formed, because the process of etching the contact plug insulating layers 160 in the horizontal direction may not be provided, the seam 160s may be prevented from being broken. Accordingly, the semiconductor device 100c having improved electrical properties and reliability may be provided.

FIG. 6 is an enlarged view illustrating a portion of a semiconductor device according to an example embodiment, illustrating a region corresponding to FIG. 2C.

Referring to FIG. 6, the semiconductor device 100d may further include a void 160V in contact plug insulating layers 160. In an example embodiment, at least one of the first contact plug insulating layers 160a and the second contact plug insulating layers 160b may include a void 160V. Referring to the process in FIG. 16, the void 160V may be formed when the contact plug insulating layers 160 do not completely fill the first tunnel portions (TL1, see FIG. 15) and the second tunnel portions (TL2, see FIG. 15). The void 160V may include air or gas formed of materials used in the process of manufacturing the semiconductor device 100d.

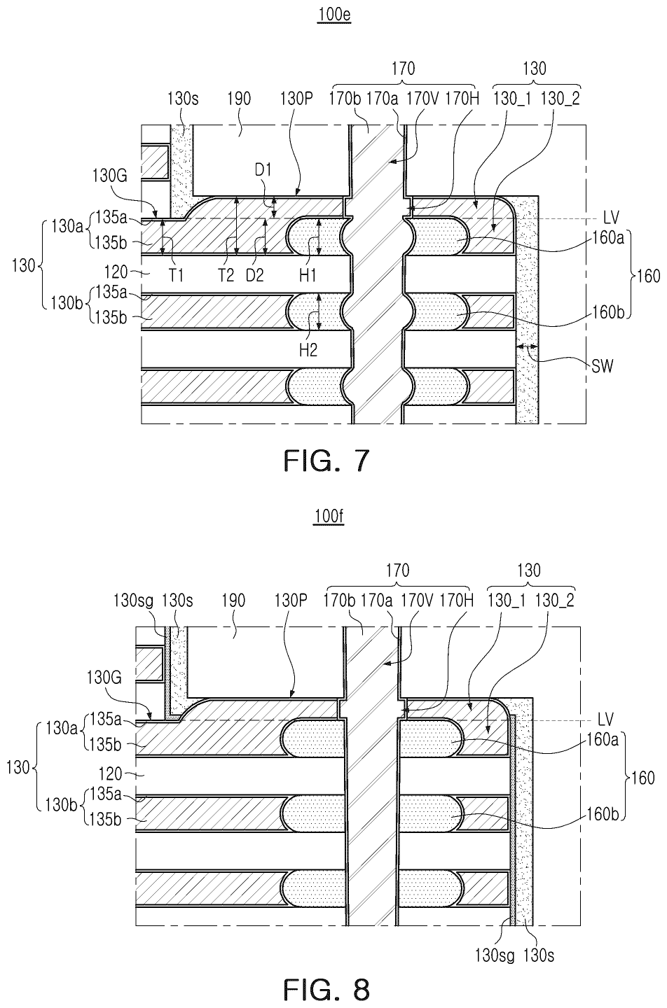

FIG. 7 is an enlarged view illustrating a portion of a semiconductor device according to an example embodiment, illustrating a region corresponding to FIG. 2C.

Referring to FIG. 7, an internal side surface of the contact plug insulating layers 160 of the semiconductor device 100e may have a concave shape. In an example embodiment, at least one of the first contact plug insulating layers 160a or the second contact plug insulating layers 160b may have a concave shape, that is an inwardly curved shape on a surface in contact with the gate contact plugs 170. Referring to the process in FIG. 19, the above shape may be formed by removing a portion of the internal side surface of the contact plug insulating layers 160 in the process of removing the sacrificial layers (122, see FIG. 18) in the second openings OH2.

FIG. 8 is an enlarged view illustrating a portion of a semiconductor device according to an example embodiment, illustrating a region corresponding to FIG. 2C.

Referring to FIG. 8, a semiconductor device 100f may further include an adhesive layer 130sg disposed between the gate electrodes 130 and the sacrificial insulating pattern 130s or between the interlayer insulating layers 120 and the sacrificial insulating pattern 130s. Referring to FIG. 12, the adhesive layer 130sg may be formed before the sacrificial insulating pattern 130s, along a staircase shape of the preliminary stack structure. The adhesive layer 130sg may improve adhesion between the sacrificial insulating pattern 130s and the preliminary stack structure. Also, the adhesive layer 130sg may control an inter-diffusion phenomenon between the sacrificial insulating pattern 130s and the preliminary stack structure. In an example embodiment, the adhesive layer 130sg may include a material different from that of the sacrificial insulating pattern 130s. For example, the adhesive layer 130sg may include silicon boron nitride (SiBN). Referring to FIG. 17, the adhesive layer 130sg may be selectively removed for the sacrificial insulating layers (118, see FIG. 16) and may be removed along with the sacrificial insulating pattern 130s

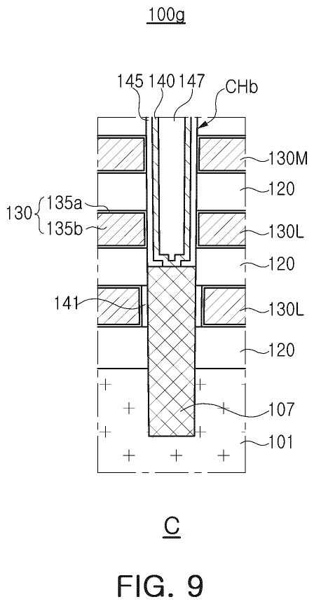

FIG. 9 is an enlarged view illustrating a portion of a semiconductor device according to an example embodiment, illustrating a region corresponding to region “C” in FIG. 2B.

Referring to FIG. 9, in a semiconductor device 100G, the memory cell region CELL may not include the first and second horizontal conductive layers 102 and 104 on the plate layer 101, differently from the example embodiment in FIGS. 2A to 2C. Also, the channel structure CHb may further include an epitaxial layer 107.

The epitaxial layer 107 may be disposed on the plate layer 101 on a lower end of the channel structure CHb and may be disposed on the side surface of at least one gate electrode 130. The epitaxial layer 107 may be disposed in a recessed region of the plate layer 101. A level of an upper surface of the epitaxial layer 107 may be higher than a level of an upper surface of a lower gate electrode 130L in a lowermost portion and lower than a level of a lower surface of a lower gate electrode 130L disposed thereabove, but example embodiments thereof are not limited thereto. The epitaxial layer 107 may be connected to the channel layer 140 through an upper surface. A gate insulating layer 141 may be further disposed between the lower gate electrode 130L in contact with the epitaxial layer 107, which may also be applied to another example embodiment.

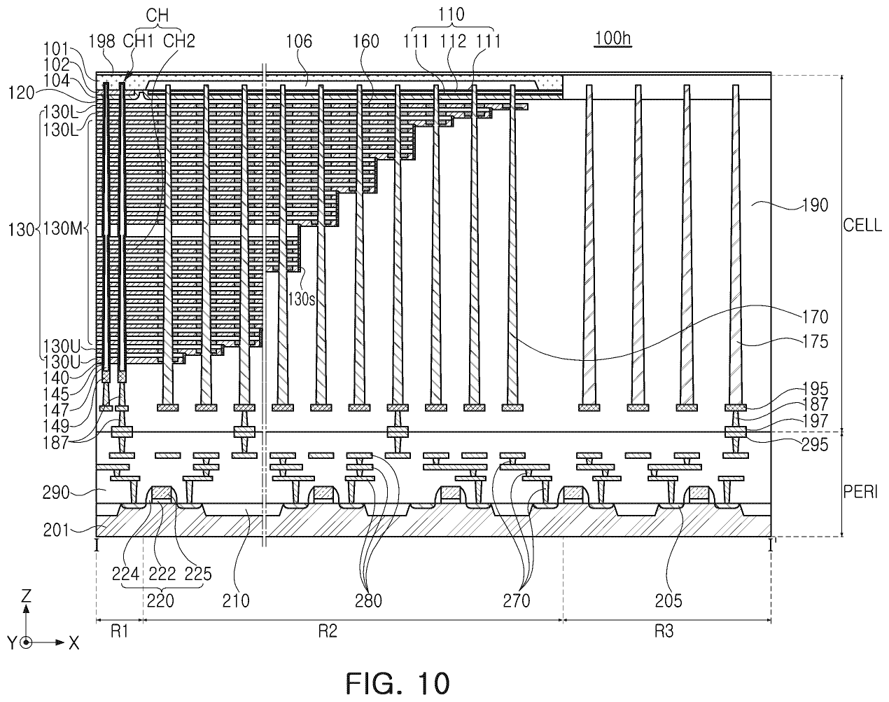

FIG. 10 is a cross-sectional view illustrating a semiconductor device according to example embodiments, illustrating a region corresponding to FIG. 2A.

Referring to FIG. 10, a semiconductor device 100H may have a structure in which a peripheral circuit region PERI and a memory cell region CELL are vertically bonded to each other. To this end, the peripheral circuit region PERI may further include first bonding metal layers 295, and the memory cell region CELL may further include upper plugs 187, second bonding metal layers 197, and a passivation layer 198 on the plate layer 101. Also, upper ends of the gate contact plugs 170 and the through-plugs 175 may be disposed in the plate layer 101.

The first bonding metal layers 295 may be disposed on the circuit contact plugs 270 and the circuit interconnection lines 280, and an upper surface thereof may be exposed to an upper surface of the peripheral circuit region PERI through the peripheral region insulating layer 290. The second bonding metal layers 197 may be disposed below the upper plugs 187 such that a lower surface thereof may be exposed to a lower surface of the memory cell region CELL through the cell region insulating layer 190. The first bonding metal layers 295 and the second bonding metal layers 197 may include a conductive material such as copper (Cu). In some example embodiments, each of the peripheral region insulating layer 290 and the cell region insulating layer 190 may further include a bonding dielectric layer surrounding a corresponding one of the first bonding metal layers 295 and the second bonding metal layers 197 and disposed at a desired (or alternatively, predetermined) depth from a corresponding one of the upper surface of the peripheral circuit region PERI and the lower surface of the memory cell region CELL. The bonding dielectric layer may include, for example, at least one of SiO, SiN, SiCN, SiOC, SiON, or SiOCN. The passivation layer 198 may be disposed on the plate layer 101 to protect the plate layer 101 and may include an insulating material.

The peripheral circuit region PERI and the memory cell region CELL may be bonded to each other by bonding between the first bonding metal layers 295 and the second bonding metal layers 197 and bonding between the bonding dielectric layers. The bonding between the first bonding metal layers 295 and the second bonding metal layers 197 may be, for example, copper (Cu)-copper (Cu) bonding, and the bonding between the defroster bonding dielectric layers may be, for example, dielectric-dielectric bonding such as SiCN—SiCN bonding. The peripheral circuit region PERI and the memory cell region CELL may be bonded to each other by hybrid bonding including copper (Cu)-copper (Cu) bonding and dielectric-dielectric bonding.

Upper ends of the gate contact plugs 170 may be disposed to be electrically isolated from each other in the plate layer 101. To this end, the plate layer 101 may include an insulating region 106, and upper ends of the gate contact plugs 170 may be disposed in the insulating region 106. However, in some example embodiments, the plate layer 101 may have a divided form such that the gate contact plugs 170 may be electrically isolated from each other instead of including the insulating region 106

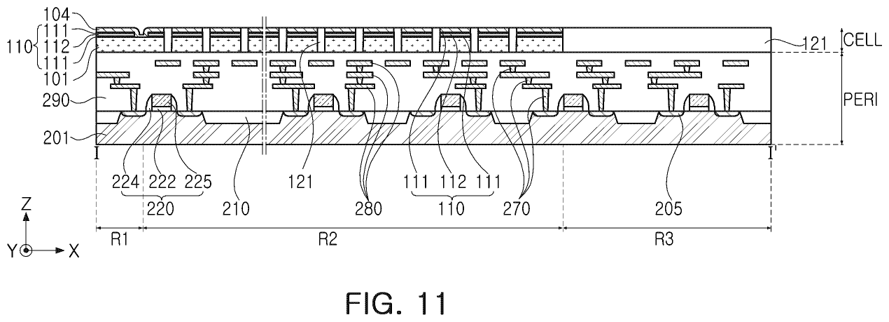

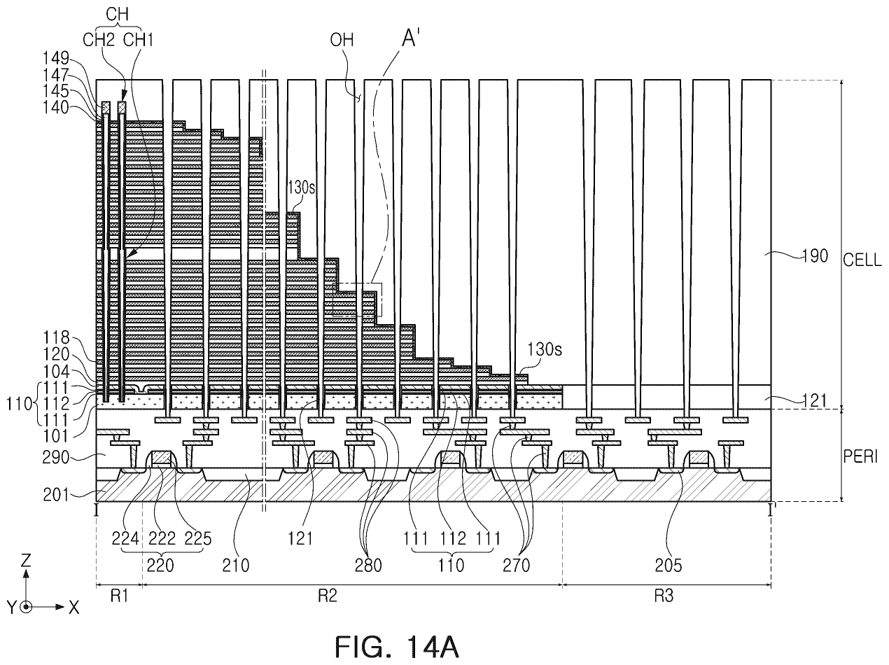

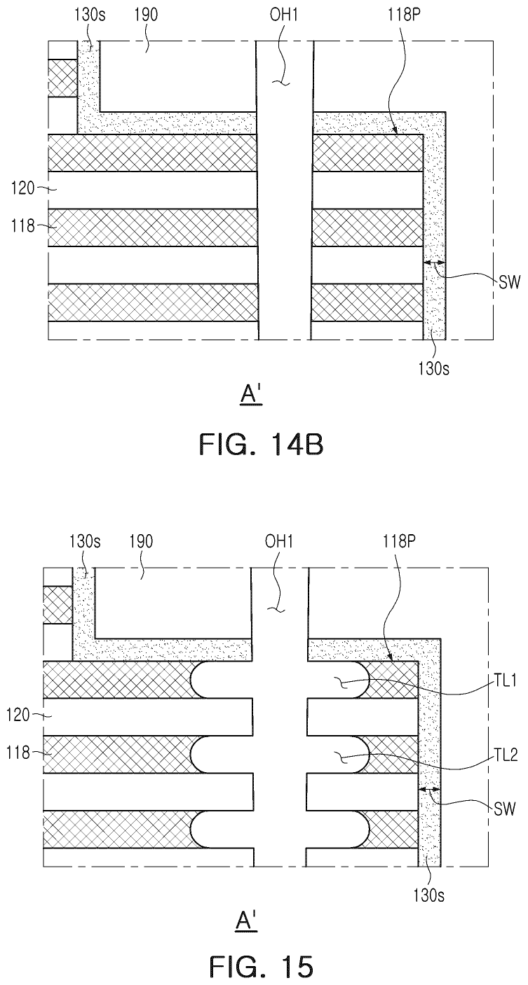

FIGS. 11 to 20 are cross-sectional views and enlarged views illustrating a method of manufacturing a semiconductor device according to an example embodiment. FIGS. 11 to 14A, and FIG. 20 illustrate a region corresponding to FIG. 2A, and FIGS. 14b to 19 illustrate an enlarged “A” region in FIG. 14A.

Referring to FIG. 11, a peripheral circuit region PERI including circuit devices 220 and lower interconnection structures may be formed on the substrate 201, and a plate layer 101, a horizontal insulating layer 110, a second horizontal conductive layer 104, and a substrate insulating layer 121 forming the memory cell region CELL may be formed on the peripheral circuit region PERI.

First, the device isolation layers 210 may be formed in the substrate 201, and a circuit gate dielectric layer 222 and a circuit gate electrode 225 may be formed in order on the substrate 201. The device isolation layers 210 may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but example embodiments thereof are not limited thereto. Thereafter, a spacer layer 224 and source/drain regions 205 may be formed on both side walls of the circuit gate dielectric layer 222 and the circuit gate electrode 225. In some example embodiments, the spacer layer 224 may include a plurality of layers. Thereafter, source/drain regions 205 may be formed by performing an ion implantation process.

Among the lower interconnection structures, the circuit contact plugs 270 may be formed by partially forming the peripheral region insulating layer 290, removing a portion by etching, and filling the removed portion with a conductive material. The circuit interconnection lines 280 may be formed, for example, by depositing a conductive material and patterning the material.

The peripheral region insulating layer 290 may include a plurality of insulating layers. The peripheral region insulating layer 290 may be formed to cover the circuit devices 220 and the lower interconnection structures by forming a portion thereof in each process forming the lower interconnection structures and forming a portion on the uppermost circuit interconnection line 280.

Thereafter, the plate layer 101 may be formed on the peripheral region insulating layer 290. The plate layer 101 may be formed of, for example, polycrystalline silicon and may be formed by a CVD process. Polycrystalline silicon included in the plate layer 101 may include impurities.

The first and second horizontal insulating layers 111 and 112 included in the horizontal insulating layer 110 may be alternately stacked on the plate layer 101. A portion of the horizontal insulating layer 110 may be replaced with the first horizontal conductive layer 102 in FIG. 2A through a subsequent process. The first horizontal insulating layers 111 may include a material different from that of the second horizontal insulating layer 112. For example, the first horizontal insulating layers 111 may be formed of the same material as that of the interlayer insulating layers 120, and the second horizontal insulating layer 112 may be formed of the same material as that of the sacrificial insulating layers 118 subsequent formed. A portion of the horizontal insulating layer 110 may be removed by a patterning process in a portion of regions (e.g., the second region R2 of the plate layer 101).

The second horizontal conductive layer 104 may be formed on the horizontal insulating layer 110 and may be in contact with the plate layer 101 in a region from which the horizontal insulating layer 110 is removed. Accordingly, the second horizontal conductive layer 104 may be bent along ends of the horizontal insulating layer 110, and may cover the ends and may extend to the plate layer 101.

The substrate insulating layer 121 may be formed to penetrate through the plate layer 101 in regions and the third region R3 in which the gate contact plugs 170 (see FIG. 2A) of the second region R2 are to be disposed. The substrate insulating layer 121 may be formed by removing a portion of the plate layer 101, the horizontal insulating layer 110, and the second horizontal conductive layer 104 and filling the insulating material. After filling the insulating material, a planarization process may be further performed using a chemical mechanical polishing or CMP process. Accordingly, an upper surface of the substrate insulating layer 121 may be substantially coplanar with an upper surface of the second horizontal conductive layer 104.

Referring to FIG. 12, a preliminary stack structure may be formed by alternately stacking the sacrificial insulating layers 118 and the interlayer insulating layers 120 included in a lower stack structure on the second horizontal conductive layer 104, and the step structure may be formed by etching the preliminary stack structure, thereby forming preliminary pads 118P. First channel sacrificial layers 116a penetrating through the lower stack structure may be formed. The sacrificial insulating layers 118 and the interlayer insulating layers 120 included in an upper stack structure may be alternatively stacked on the lower stack structure, a step structure may be formed, and sacrificial insulating patterns 130s may be formed. Second channel sacrificial layers 116b penetrating through the upper stack structure may be formed.

First, a preliminary stack structure may be formed by alternately stacking the sacrificial insulating layers 118 and the interlayer insulating layers 120 on the second horizontal conductive layer 104. In this process, the sacrificial insulating layers 118 and the interlayer insulating layers 120 may be formed in a level region in which first channel structures CH1 (see FIG. 2A) are disposed. An upper interlayer insulating layer 125 having a relatively great thickness may be formed on the uppermost portion.

The sacrificial insulating layers 118 may be replaced with gate electrodes 130 (see FIG. 2A) through a subsequent process. The sacrificial insulating layers 118 may be formed of a material different from that of the interlayer insulating layers 120, and may be formed of a material etched with etch selectivity under specific etching conditions with respect to the interlayer insulating layers 120. For example, the interlayer insulating layer 120 and the upper interlayer insulating layer 125 may include at least one of silicon oxide or silicon nitride, and the sacrificial insulating layers 118 may be formed of a material different from that of the interlayer insulating layer 120 selected from among silicon, silicon oxide, silicon carbide, and silicon nitride. In some example embodiments, the interlayer insulating layers 120 may not have the same thickness. The thicknesses of the interlayer insulating layers 120 and the sacrificial insulating layers 118 and the number of films forming the interlayer insulating layers 120 and the sacrificial insulating layers 118 may be varied according to example embodiments.

Thereafter, in the second region R2, a photolithography process and an etching process for the sacrificial insulating layers 118 may be repeatedly performed using a mask layer such that the upper sacrificial insulating layers 118 may extend shorter than the lower sacrificial insulating layers 118. Accordingly, the sacrificial insulating layers 118 may form a step structure of a staircase shape by a desired (or alternatively, predetermined) unit, and preliminary pads 118P disposed on the sacrificial insulating layers 118 may be exposed upwardly.

The first channel sacrificial layers 116a may be formed in a region corresponding to the first channel structures CH1 (see FIG. 2A) in the first region R1. The first channel sacrificial layers 116a may be formed by forming lower channel holes to penetrate through the lower stack structure and depositing a material included in the first channel sacrificial layers 116a on the lower channel holes. The first channel sacrificial layers 116a may include, for example, polycrystalline silicon.

Thereafter, the sacrificial insulating pattern 130s may cover the first preliminary pads 118P along the staircase shape of the preliminary stack structure. The sacrificial insulating pattern 130s may be formed through a deposition process. A thickness of the sacrificial insulating pattern 130s may range from about 50% to about 110% of the thickness of the sacrificial insulating layers 118, but example embodiments thereof are not limited thereto. The sacrificial insulating pattern 130s may include boron (B), and may include, for example, at least one of boron nitride (BN) or boron carbon nitride (BCN).

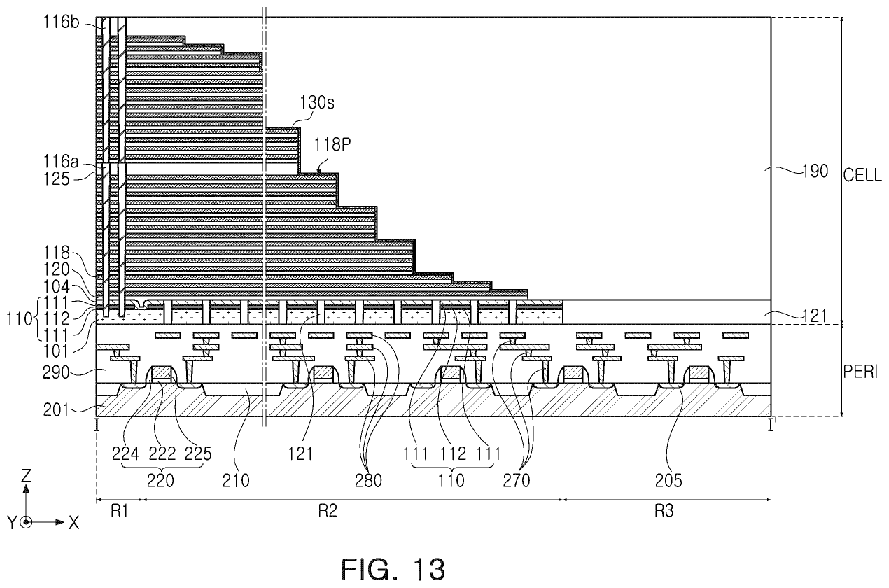

Referring to FIG. 13, second channel sacrificial layers 116b penetrating through the upper stack structure and the sacrificial insulating pattern 130s may be formed.

The second channel sacrificial layers 116b may be formed by forming upper channel holes on the first channel sacrificial layers 116a to penetrate through the upper stack structure and the sacrificial insulating pattern 130s to expose an upper end of the first channel sacrificial layers 116a, and depositing a material forming the second channel sacrificial layers 116b on the upper channel holes. The second channel sacrificial layers 116b may include, for example, polycrystalline silicon.

Referring to FIGS. 14A and 14B, the first and second sacrificial channel layers 116a and 116b may be formed, the channel structures CH may be formed, and first openings OH1 may be formed.

The channel structures CH may be formed by forming channel holes by removing the first and second sacrificial channel layers 116a and 116b, and filling the channel holes. For example, channel structures CH may be formed by forming a cell region insulating layer 190 covering the stack structure, and forming the gate dielectric layer 145, the channel layer 140, the channel buried insulating layer 147, and the channel pad 149 in order on the cell region insulating layer 190 and the channel holes penetrating the stack structure. The channel layer 140 may be formed of a conductive the lower step, for example polycrystalline silicon.

In an example embodiment, in the stack structure, a lower stack structure may be formed, and then a lower step structure and a portion of a cell region insulating layer 190 covering the lower step may be formed, an upper stack structure may be formed on the lower stack structure, and an upper step structure and the other portion of the cell region insulating layer 190 may be further formed. In this case, to form the channel structures CH, a lower channel hole penetrating through the lower step structure and an upper channel hole penetrating through the upper step structure may be separately formed. Accordingly, the channel structures CH may include a first channel structure CH1 corresponding to the lower channel hole and a second channel structure CH2 corresponding to the upper channel hole.

Thereafter, the first openings OH may be formed in a region at which the gate contact plugs 170 and the through-plugs 175 in FIG. 2A are to be formed. Before forming the first openings OH, a portion of the cell region insulating layer 190 covering the channel structures CH may be further formed. The first openings OH1 may have a cylindrical hole shape, may penetrate through the substrate insulating layer 121 and may extend to the peripheral circuit region PERI.

Referring to FIG. 15, the first and second tunnel portions TL1 and TL2 may be formed by removing a portion of the sacrificial insulating layers 118 and the preliminary pads 118P exposed through the first openings OH1.

First, the first and second tunnel portions TL1 and TL2 may be formed by removing the sacrificial insulating layers 118 and the preliminary pads 118P to a desired (or alternatively, predetermined) length around the first openings OH1 by filling an etchant through the first openings OH. The first and second tunnel portions TL1 and TL2 may include the first tunnel portions TL1 penetrating through the sacrificial insulating layers 118 of the preliminary pads 118P and the second tunnel portions TL2 penetrating through the sacrificial insulating layers 118 disposed below the second preliminary pads 118P.

When the sacrificial insulating layers 118 are formed to have the same thickness, the first tunnel portions TL1 may be formed to have substantially the same length as those of second tunnel portions TL2, which may be because the sacrificial insulating pattern 130s may have etching selectivity with respect to the preliminary pads 118P and the sacrificial insulating layers 118 under specific etching conditions.

In the example embodiment, each of the first tunnel portions TL1 may have a shape symmetrical or close to symmetrical vertically with respect to a center in the Z-direction. Each of the first and second tunnel portions TL1 and TL2 may have a rectangular shape having a rounded corner or a rectangular shape with angular corners on a cross-sectional view. However, the shapes of the first and second tunnel portions TL1 and TL2 are not limited to the shapes illustrated in FIG. 15 and may be varied.

Referring to FIG. 16, the contact plug insulating layers 160 and the sacrificial layer 122 may be formed in the first and second tunnel portions TL1, TL2 and the first openings OH.

First, the contact plug insulating layers 160 may be deposited by, for example, an ALD process. The contact plug insulating layers 160 may be formed to completely fill the first and second tunnel portions TL1 and TL2 having substantially the same thickness. The contact plug insulating layers 160 may include, for example, an insulating material such as oxide or silicon oxide.

Thereafter, when the contact plug insulating layers 160 are present on the side wall of the first openings OH1, the contact plug insulating layers 160 may be removed and the sacrificial layer 122 may be formed from the first openings OH1. The sacrificial layer 122 may be formed of an insulating material such as silicon oxide, silicon nitride, silicon oxynitride, or a combination thereof. The sacrificial layer 122 may be formed of a material different from that of the sacrificial insulating layers 118 and the nitride layer 150.

Because a process for separately removing the first contact insulating layer 160a is not desired in the example embodiment, difficulty of the process may be reduced.

Referring to FIG. 17, the third and fourth tunnel portions TL3 and TL4 may be formed by forming an isolation opening and removing the sacrificial insulating pattern 130s and the sacrificial insulating layers 118.

First, the isolation openings extending to the plate layer 101 through the sacrificial insulating layers 118 and the interlayer insulating layers 120 may be formed in positions of the first and second isolation regions MS1 and MS2 (see FIG. 1). By performing an etch-back process while forming sacrificial spacer layers in the isolation openings, in the first region R1, the horizontal insulating layer 110 may be selectively removed, and a portion of the exposed gate dielectric layer 145 may also be removed. After forming a first horizontal conductive layer 102 by depositing a conductive material on the region from which the horizontal insulating layer 110 is removed, the sacrificial spacer layers may be removed in the openings. Through this process, a first horizontal conductive layer 102 may be formed in the first region R1.

Thereafter, the sacrificial insulating pattern 130s may be selectively removed with respect to the cell region insulating layer 190, the contact plug insulating layers 160, the sacrificial layer 122, and the sacrificial insulating layers 118 using, for example, a wet etching process. At least a portion of the sacrificial insulating pattern 130s may be removed from the pad region 130P and may remain on a side wall of the interlayer insulating layers 120. Accordingly, a third tunnel portion TL3 may be formed in the pad region 130P.

Thereafter, the sacrificial insulating layers 118 may be selectively removed with respect to the interlayer insulating layers 120, the contact plug insulating layers 160, the sacrificial layer 122, and the remaining sacrificial insulating pattern 130s. Accordingly, a fourth tunnel portion TL4 may be formed between the interlayer insulating layers 120.

Because the example embodiment does not need a process for removing the sacrificial insulating pattern 130s from a side surface of the preliminary stack structure, difficulty of the process may be reduced. In some example embodiments, the sacrificial insulating layers 118 and the sacrificial insulating pattern 130s may be removed simultaneously, or the sacrificial insulating layer 118 may be removed first and then the sacrificial insulating pattern 130s may be removed.

Referring to FIG. 18, the gate electrodes 130 may be formed by filling conductive material in the third and fourth tunnel portions TL3 and TL4.

The conductive material included in the gate electrodes 130 may fill the third and fourth tunnel portions TL3 and TL4. The conductive material may include a metal, polycrystalline silicon or metal silicide material. After forming the gate electrodes 130, an isolation insulating layer (105, see FIG. 2B) may be formed in the openings formed in the first and second isolation regions MS1 and MS2. The first and second gate electrodes 130a and 130b may include a first layer 135a and a second layer 135b. The first layer 135a may cover an upper surface, a lower surface, and a side surface of the second layer 135b and may extend to a region between the channel structure CH and the second layer 135b. The first layer 135a may include a high-x dielectric material such as aluminum oxide (AlO), and the second layer 135b may include titanium (Ti), titanium nitride (TiN), tantalum (Ta), tantalum nitride (TaN), tungsten (W), or tungsten nitride (WN). In some example embodiments, the first and second gate electrodes 130a and 130b may include polycrystalline silicon or a metal-semiconductor compound.

Referring to FIG. 19, the second openings OH may be formed by removing the sacrificial layer 122.

After selectively removing the sacrificial layer 122, a portion of the exposed first gate electrode 130a may be removed through an etching process. In this case, in the pad regions 130P, the first gate electrode 130a on the upper surface of the first contact plug insulating layer 160a may be exposed, and the second gate electrode 130b may not be exposed below the first gate electrode 130a by the second contact plug insulating layer 160b. Accordingly, the second gate electrode 130b disposed below the first gate electrode 130a may not be exposed from the second openings OH2 by the second contact plug insulating layers 160b, and the second gate electrode 130b and the second openings OH2 may be isolated from each other by the second contact plug insulating layer 160b.

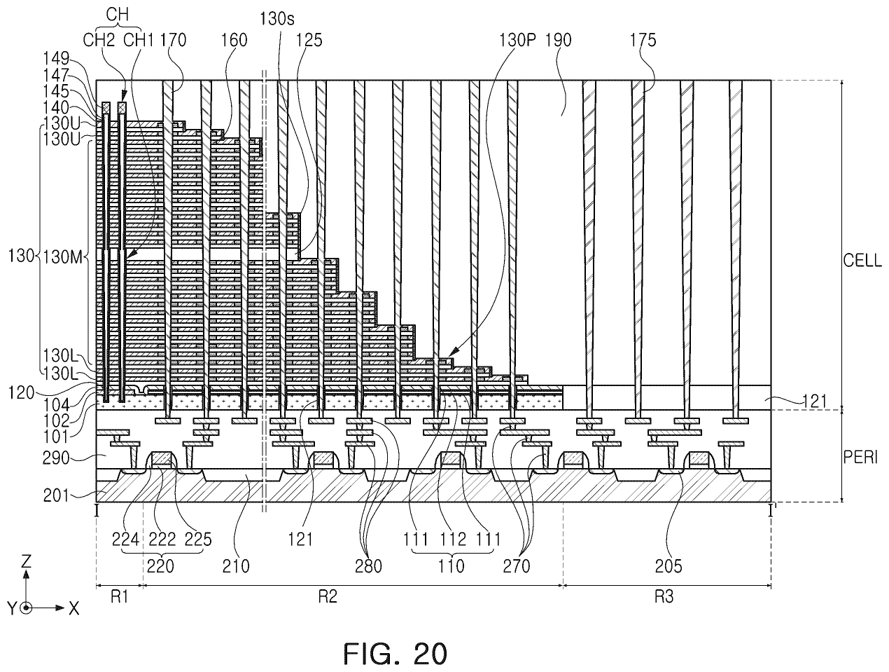

Referring to FIG. 20, the gate contact plugs 170 and the through-plugs 175a may be formed by depositing a conductive material in the second openings OH2.

After exposing the circuit interconnection lines 280 by removing the pad layers 285 at the lower end of the openings OH, the conductive material may be deposited. Because the gate contact plugs 170 and the through-plugs 175 are formed together in the same process, the gate contact plugs 170 and the through-plugs 175 may have the same structure. The gate contact plugs 170 may be formed to have a horizontal extension portion 170H (see FIG. 2C) in the pad regions 130P, and accordingly, the gate contact plugs 170 may be physically and electrically connected to the gate electrodes 130.

Thereafter, referring to FIG. 2A together, by forming the cell interconnection lines 195 connected to upper ends of the gate contact plugs 170 and the through-plugs 175, the semiconductor device 100 may be manufactured.

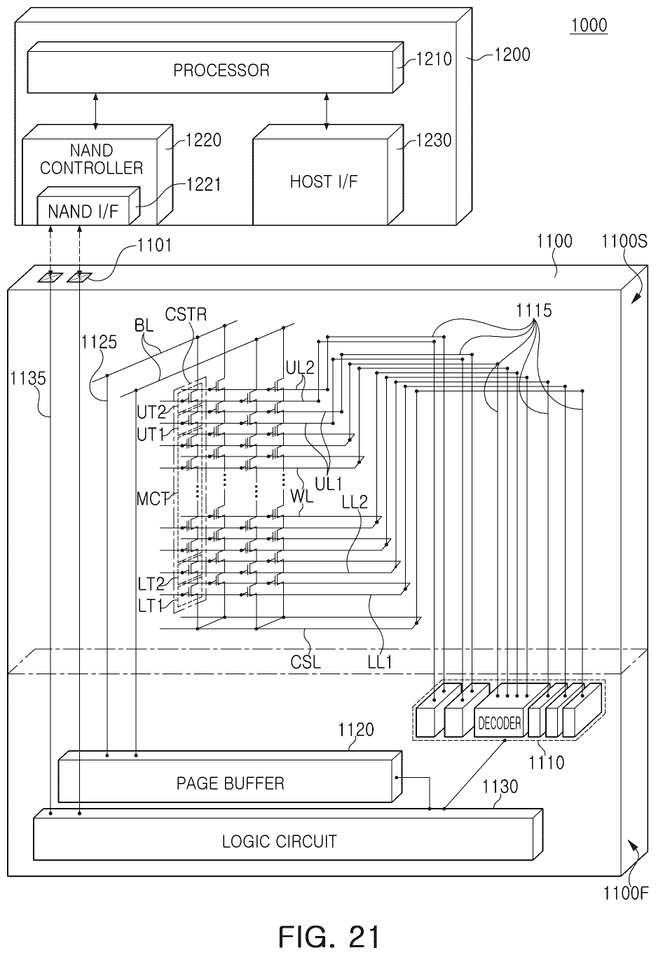

FIG. 21 is a view illustrating a data storage system including a semiconductor device according to an example embodiment.

Referring to FIG. 21, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 10. The semiconductor device 1100 may include a first semiconductor structure 1100F and a second semiconductor structure 1100S on the first semiconductor structure 1100F. In the example embodiments, the first semiconductor structure 1100F may be disposed on the side of the second semiconductor structure 1100S. The first semiconductor structure 1100F may be implemented as a peripheral circuit structure including a decoder circuit 1110, a page buffer 1120, and a logic circuit 1130. The second semiconductor structure 1100S may be implemented as a memory cell structure including a bit line BL, a common source line CSL, word lines WL, first and second gate upper lines UL1 and UL2, first and second gate lower lines LL1 and LL2 and memory cell strings CSTR disposed between the bit line BL and the common source line CSL.

In the second semiconductor structure 1100S, each of the memory cell strings CSTR may include lower transistors LT1 and LT2 adjacent to the common source line CSL, the upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in example embodiments.

In the example embodiment, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The word lines WL may be configured as gate electrodes of the memory cell transistors MCT, and the gate upper lines UL1 and UL2 may be configured as gate electrodes of the upper transistors UT1 and UT2, respectively.

In the example embodiment, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first semiconductor structure 1100F to the second semiconductor structure 1100S. The bit lines BL may be electrically connected to the page buffer 1120 through second connection interconnections 1125 extending from the first structure 110F to the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first semiconductor structure 1100F to the second semiconductor structure 1100S.

The controller 1200 may include a processor 1210, a NAND controller 1220, and a host interface 1230. In some example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a desired (or alternatively, predetermined) firmware, and may access the semiconductor device 1100 by controlling the NAND controller 1220. The NAND controller 1220 may include a NAND interface 1221 processing communication with the semiconductor device 1100. Through the NAND interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

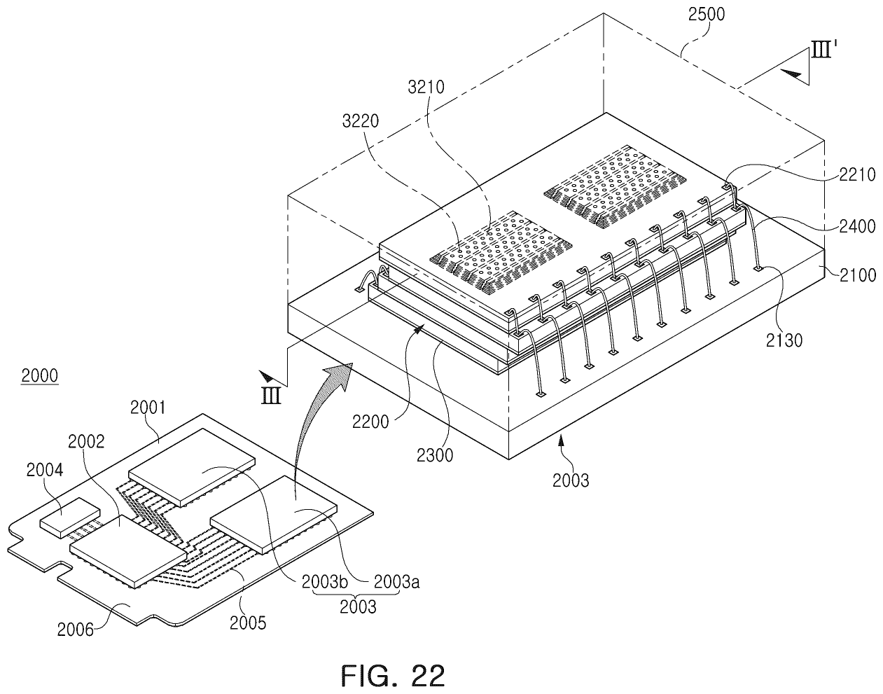

FIG. 22 is a perspective view illustrating a data storage system including a semiconductor device according to an example embodiment.

Referring to FIG. 22 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiment, the data storage system 2000 may communicate with an external host according to one of interfaces from among universal serial bus (USB), peripheral component interconnect express (PCI-express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 21. Each of the semiconductor chips 2200 may include gate stack structures 3210 and channel structures 3220. Each of the semiconductor chips 2200 may include the semiconductor device described in the aforementioned example embodiment with reference to FIGS. 1 to 10.

In the example embodiment, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiment, the controller 2002 and the semiconductor chips 2200 may be included in a single package. In some example embodiment, the controller 2002 and the semiconductor chips 2200 may be mounted on a separate interposer substrate different from the main board 2001, and the controller 2002 and the semiconductor chips 2200 may be connected to each other interconnection formed on the interposer substrate.

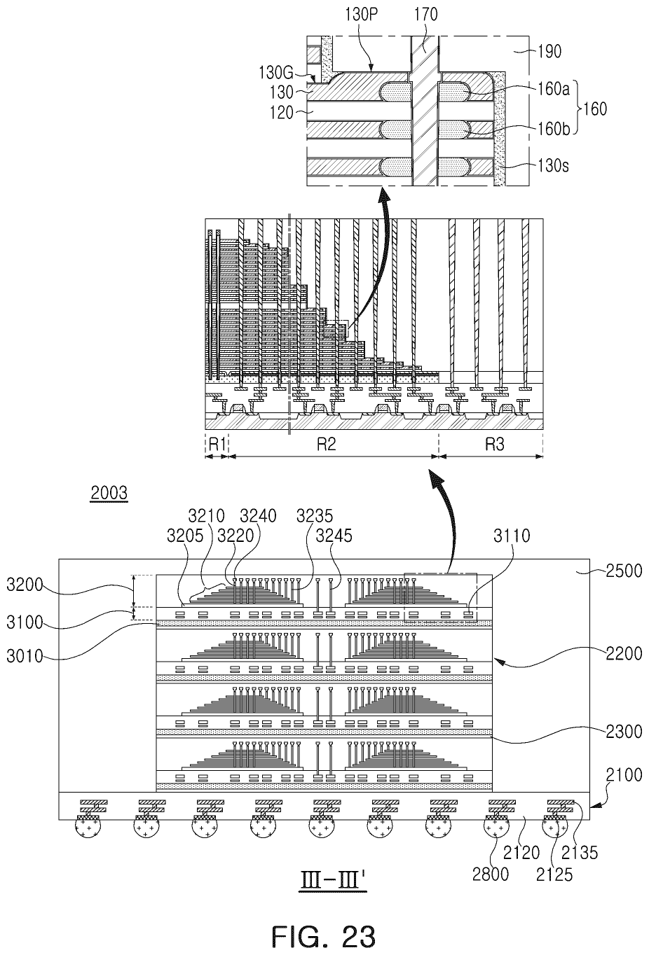

FIG. 23 is a cross-sectional view illustrating a semiconductor package according to an example embodiment. FIG. 23 illustrates an example embodiment of the semiconductor package 2003 in FIG. 22, illustrating a region of the semiconductor package 2003 taken along line in FIG. 22.

Referring to FIG. 23, in the semiconductor package 2003, the package substrate 2100 may be implemented as a printed circuit board. The package substrate 2100 may include a package substrate body 2120, package upper pads 2130 (see FIG. 22) disposed on the upper surface of the package substrate body 2120, lower pads 2125 disposed on the lower surface of the package substrate body 2120 or exposed through the lower surface, and internal interconnections 2135 electrically connecting the upper pads 2130 to the lower pads 2125 in the package substrate body 2120. Upper pads 2130 may be electrically connected to the connection structures 2400. The lower pads 2125 may be connected to the interconnection patterns 2005 of the main substrate 2010 of the data storage system 2000 through the conductive connections 2800 as illustrated in FIG. 22.

Each of the semiconductor chips 2200 may include a first semiconductor structure 3100 and a second semiconductor structure 3200 stacked in order on the semiconductor substrate 3010 and the semiconductor substrate 3010. The first semiconductor structure 3100 may include a peripheral circuit region including peripheral interconnections 3110. The second semiconductor structure 3200 may include a common source line 3205, a gate stack structure 3210 on the common source line 3205, channel structures 3220 penetrating through the gate stack structure 3210, isolation regions, bit lines 3240 electrically connected to memory channel structures 3220, and gate connection wires 3235 electrically connected to the word lines WL of the gate stack structure 3210 (see FIG. 21). As described above with reference to FIGS. 1 to 10, each of the semiconductor chips 2200 may include, in the pad region 130P, first contact plug insulating layers 160a disposed on the interlayer insulating layers 120, surrounding the gate contact plugs 170, and vertically overlapping the first gate electrodes 130a in the pad region 130P, and a sacrificial insulating pattern 130s covering a portion of the pad region 130P, at least a portion of the side surface of the first gate electrode 130a, and at least a portion of the side surface of the interlayer insulating layers 120 and including boron (B).

Each of the semiconductor chips 2200a may further include a through-interconnection 3245 electrically connected to the peripheral interconnections 3110 of the first semiconductor structure 3100 and extending into the second semiconductor structure 3200. The through-interconnection 3245 may be disposed on an external side of the gate stack structure 3210 and may further be disposed to penetrate through the gate stack structure 3210. Each of the semiconductor chips 2200 may further include an input/output pad 2210 (see FIG. 22) electrically connected to the peripheral interconnections 3110 of the first semiconductor structure 3100.

According to the aforementioned example embodiments, by forming a first contact plug insulating layer in the pad region and replacing a portion of the sacrificial insulating pattern with a gate electrode, a structure that the gate electrode may cover the side surface and the upper surface of the first contact plug insulating layer and be electrically connected to the gate contact plug on an upper surface of the first contact plug insulating layer may be provided. Through this, a semiconductor device having improved electrical properties and reliability, and a data storage system including the same may be provided.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a substrate and circuit devices on the substrate; and
a second semiconductor structure on the first semiconductor structure,
wherein the second semiconductor structure includes,
a plate layer having a first region and a second region,
gate electrodes stacked and spaced apart from each other in a first direction on the first region, the gate electrodes extending by different lengths in a second direction on the second region, the gate electrodes each including a pad region having an upper surface exposed upwardly in the second region and a stack region other than the pad region, the gate electrodes including a first gate electrode and a second gate electrode below the first gate electrode,
interlayer insulating layers alternately stacked with the gate electrodes,
channel structures penetrating through the gate electrodes, the channel structures extending in the first direction, the channel structures each including a channel layer,
a gate contact plug penetrating through the pad region of the first gate electrode and the stack region of the second gate electrode, the gate contact plug electrically connected to the first gate electrode, the gate contact plug spaced apart from the second gate electrode,
a first contact plug insulating layer on the interlayer insulating layers in the pad region of the first gate electrode, the first contact plug insulating layer surrounding the gate contact plug, the first contact plug insulating layer vertically overlapping the first gate electrode, and
second contact plug insulating layers alternating with the interlayer insulating layers below the pad region of the first gate electrode, the second contact plug insulating layers surrounding the gate contact plug.

2. The semiconductor device of claim 1, wherein the first gate electrode covers a side surface and an upper surface of the first contact plug insulating layer.

3. The semiconductor device of claim 1, wherein the first gate electrode is in contact with the gate contact plug on an upper surface of the first contact plug insulating layer.

4. The semiconductor device of claim 1, further comprising:
a sacrificial insulating pattern covering a portion of the pad region of the first gate electrode, at least a portion of a side surface of the first gate electrode, and at least a portion of a side surface of the interlayer insulating layers, the sacrificial insulating pattern including boron (B).

5. The semiconductor device of claim 1, wherein at least one of the first contact plug insulating layer and the second contact plug insulating layers includes at least one of a seam or a void extending in the second direction.

6. The semiconductor device of claim 1, wherein the first gate electrode includes a first portion covering a side surface and an upper surface of the first contact plug insulating layer and a second portion between an upper surface of the first contact plug insulating layer and a lower surface of the first contact plug insulating layer, the first portion being at a level higher than a level of the upper surface of the first contact plug insulating layer.

7. The semiconductor device of claim 6, wherein a thickness of the first portion is equal to or smaller than a thickness of the second portion.

8. The semiconductor device of claim 6, wherein a thickness of the first portion is greater than a thickness of the second portion.

9. The semiconductor device of claim 1,
wherein the first contact plug insulating layer has a first thickness, and
wherein each of the second contact plug insulating layers has a second thickness equal to the first thickness.

10. The semiconductor device of claim 1, wherein each of the gate electrodes has a first gate thickness in the stack region and a second gate thickness greater than the first gate thickness in the pad region.

11. The semiconductor device of claim 1,
wherein the gate contact plug includes a vertical extension portion extending in the first direction and a horizontal extension portion extending from the vertical extension portion in the second direction perpendicular to the first direction and in contact with the pad region, and
wherein a first length of the vertical extension portion in the second direction is smaller than a second length of the first contact plug insulating layer in the second direction.

12. The semiconductor device of claim 11, wherein the second length is equal to a third length of the second contact plug insulating layers in the second direction.

13. A semiconductor device, comprising:
a plate layer having a first region and a second region;
gate electrodes stacked and spaced apart from each other in a first direction on the first region, the gate electrodes extending by different lengths in a second direction on the second region, the gate electrodes each including a pad region having an upper surface exposed upwardly in the second region and a stack region other than the pad region, the gate electrodes including a first gate electrode and a second gate electrode below the first gate electrode;
interlayer insulating layers alternately stacked with the gate electrodes;
a gate contact plug penetrating through the pad region of the first gate electrode and the stack region of the second gate electrode, the gate contact plug connected to the first gate electrode, the gate contact plug spaced apart from the second gate electrode;
a contact plug insulating layer on the interlayer insulating layers in the pad region of the first gate electrode, the contact plug insulating layer surrounding the gate contact plug; and
a sacrificial insulating pattern covering a portion of the pad region of the first gate electrode, at least a portion of a side surface of the first gate electrode, and at least a portion of a side surface of the interlayer insulating layers, the sacrificial insulating pattern including boron (B).

14. The semiconductor device of claim 13, wherein the sacrificial insulating pattern further includes nitrogen (N) and has an amorphous structure.

15. The semiconductor device of claim 14,
wherein the sacrificial insulating pattern further includes carbon (C), and
wherein carbon (C) is in a range of 10 at % or less.

16. The semiconductor device of claim 13,
wherein the first gate electrode includes a first portion covering a side surface and an upper surface of the contact plug insulating layer and a second portion between the upper surface of the contact plug insulating layer and a lower surface of the contact plug insulating layer, the first portion being on a level higher than a level of the upper surface of the contact plug insulating layer, and
wherein a thickness of the sacrificial insulating pattern is same as a thickness of the first portion.

17. The semiconductor device of claim 16, wherein the first gate electrode includes a protrusion portion protruding from a side surface of the second portion toward an upper portion of the sacrificial insulating pattern.

18. The semiconductor device of claim 17, wherein the protrusion portion covers an upper surface of the sacrificial insulating pattern.

19. The semiconductor device of claim 13, further comprising:
an adhesive layer between the gate electrodes and the sacrificial insulating pattern or between the interlayer insulating layers and the sacrificial insulating pattern.

20. A data storage system, comprising:
a semiconductor storage device including a first semiconductor structure including a substrate and circuit devices on the substrate and a second semiconductor structure on the first semiconductor structure; and
a controller electrically connected to the semiconductor storage device through an input/output pad and configured to control the semiconductor storage device,
wherein the second semiconductor structure includes,
a plate layer having a first region and a second region,
gate electrodes stacked and spaced apart from each other in a first direction on the first region, the gate electrodes extending by different lengths in a second direction on the second region, the gate electrodes each including a pad region having an upper surface exposed upwardly in the second region and a stack region other than the pad region, the gate electrodes including a first gate electrode and a second gate electrode below the first gate electrode,
interlayer insulating layers alternately stacked with the gate electrodes,
channel structures penetrating through the gate electrodes, extending in the first direction, the channel structures each including a channel layer,
a gate contact plug penetrating through the pad region of the first gate electrode and the stack region of the second gate electrode, the gate contact plug electrically connected to the first gate electrode, and the gate contact plug spaced apart from the second gate electrode,
a first contact plug insulating layer on the interlayer insulating layers in the pad region of the first gate electrode, the first contact plug insulating layer surrounding the gate contact plug, and the first contact plug insulating layer vertically overlapping the first gate electrode,
second contact plug insulating layers alternating with the interlayer insulating layers below the pad region of the first gate electrode, and the second contact plug insulating layers surrounding the gate contact plug, and
a sacrificial insulating pattern covering a portion of the pad region of the first gate electrode, at least a portion of a side surface of the first gate electrode, and at least a portion of a side surface of the interlayer insulating layers.
